(19) United States
(12) Patent Application Publication
(10) Pub. No.: US 2026/0006802 A1
(43) Pub. Date: Jan. 1, 2026

(54) HIGH BANDWIDTH FLASH MEMORY CONTAINING A STACK OF BONDED LOGIC AND MEMORY DIE ASSEMBLIES AND METHODS FOR FORMING THE SAME

(71) Applicant: Sandisk Technologies, Inc., Milpitas, CA (US)

(72) Inventors: Mitsuteru MUSHIGA, Kuwana (JP); Masaaki HIGASHITANI, Cupertino, CA (US)

(21) Appl. No.: 18/811,118

(22) Filed: Aug. 21, 2024

Related U.S. Application Data
(60) Provisional application No. 63/665,731, filed on Jun. 28, 2024.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2225/06541; H01L 2924/1431; H01L 2924/14511

(57) ABSTRACT

A method of forming a semiconductor includes bonding a first memory die to a first memory-controller die to form a first bonded assembly, bonding second memory die to a second memory-controller die to form a second bonded assembly, and bonding the first bonded assembly to the second bonded assembly to form a memory stack.

### FIELD

The present disclosure relates generally to the field of semiconductor devices, and particularly to a high bandwidth flash memory containing a stack of bonded logic and memory die assemblies and methods for manufacturing the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprises a plurality stacked bonded assemblies. Each of the bonded assemblies contains a respective unit bonded assembly of a respective memory die including a respective three-dimensional array of memory elements and an array of vertical semiconductor channels, and a respective memory-controller die including a respective memory controller circuit configured to control operation of the respective three-dimensional array of memory elements. Each vertically neighboring pair of bonded assemblies of the plurality of bonded assemblies is bonded to each other through a respective pair of arrays of bonding structures such that electrically conductive paths vertically extend from a first horizontal plane including a bottom surface of a bottommost bonded assembly of the plurality of bonded assemblies at least to a second horizontal plane including a bottom surface of a topmost bonded assembly of the plurality of bonded assemblies.

According to another aspect of the present disclosure, a method of forming a semiconductor includes bonding a first memory die to a first memory-controller die to form a first bonded assembly, bonding second memory die to a second memory-controller die to form a second bonded assembly, and bonding the first bonded assembly to the second bonded assembly to form a memory stack.

### BRIEF DESCRIPTION OF THE DRAWINGS

FIG. 1 is a schematic vertical cross-sectional view of a first exemplary structure for forming a memory die after formation of a backside dielectric layer, in-process source-level material layers, an alternating stack of insulating layers and sacrificial material layers having stepped surfaces, and a retro-stepped dielectric material portion over a carrier substrate according to an embodiment of the present disclosure.

FIG. 2A is a schematic vertical cross-sectional view of the first exemplary structure after forming memory openings according to an embodiment of the present disclosure. FIG. 2B is a top-down view of the first exemplary structure of FIG. 2A. The vertical plane A-A′ is the cut plane of the vertical cross-sectional view of FIG. 2A. FIG. 2C is a top-down view of an in-process memory die including the first exemplary structure at the processing steps of FIGS. 2A and 2B.

FIGS. 3A-3D are sequential vertical cross-sectional views of a memory opening during formation of a memory opening fill structure according to an embodiments of the present disclosure.

FIG. 4 is a vertical cross-sectional view of the first exemplary structure after formation of memory opening fill structures according to an embodiment of the present disclosure.

FIG. 5A is a vertical cross-sectional view of the first exemplary structure after formation of a contact-level dielectric layer, a patterned hard mask layer, lateral isolation trenches, and discrete through-stack openings according to an embodiment of the present disclosure. FIG. 5B is a top-down view of the first exemplary structure of FIG. 5A. The vertical plane A-A′ is the cut plane of the vertical cross-sectional view of FIG. 5A. FIG. 5C is a top-down view of an in-process memory die including the first exemplary structure at the processing steps of FIGS. 2A and 2B.

FIG. 6 is a vertical cross-sectional view of the first exemplary structure after vertical extension of the discrete through-stack openings according to an embodiment of the present disclosure.

FIG. 7 is a vertical cross-sectional view of the first exemplary structure after formation of sacrificial lateral isolation trench fill structures and sacrificial through-stack opening fill structures according to an embodiment of the present disclosure.

FIG. 8 is a vertical cross-sectional view of the first exemplary structure after removal of the sacrificial lateral isolation trench fill structures according to an embodiment of the present disclosure.

FIG. 9 is a vertical cross-sectional view of the first exemplary structure after formation of a source cavity according to an embodiment of the present disclosure.

FIG. 10 is a vertical cross-sectional view of the first exemplary structure after formation of a source contact layer and dielectric capping liners according to an embodiment of the present disclosure.

FIG. 11 is a vertical cross-sectional view of the first exemplary structure after formation of laterally-extending cavities according to an embodiment of the present disclosure.

FIG. 12 is a vertical cross-sectional view of the first exemplary structure after formation of electrically conductive layers according to an embodiment of the present disclosure.

FIG. 13 is a vertical cross-sectional view of the first exemplary structure after formation of lateral isolation trench fill structures and contact via structures according to an embodiment of the present disclosure.

FIG. 14 is a vertical cross-sectional view of the first exemplary structure after removal of the sacrificial through-stack opening fill structures according to an embodiment of the present disclosure.

FIG. 15 is a vertical cross-sectional view of the first exemplary structure after formation of tubular dielectric spacers and through-stack via structures according to an embodiment of the present disclosure.

FIG. 16 is a vertical cross-sectional view of the first exemplary structure after formation of layer contact via structures, drain contact via structures, and peripheral connection via structures according to an embodiment of the present disclosure.

FIG. 17 is a vertical cross-sectional view of the first exemplary structure after formation of a memory die according to an embodiment of the present disclosure.

FIG. 18 is a vertical cross-sectional view of a second exemplary structure for forming a memory-controller die after formation of controller semiconductor devices and controller lower-level dielectric material layers according to an embodiment of the present disclosure.

FIG. 19 is a vertical cross-sectional view of the second exemplary structure after formation of through-substrate via structures according to an embodiment of the present disclosure.

FIG. 20 is a vertical cross-sectional view of the second exemplary structure after formation of a memory-controller die according to an embodiment of the present disclosure.

FIG. 21 is a vertical cross-sectional view of an exemplary bonded assembly of a memory die and a memory-controller die according to an embodiment of the present disclosure.

FIG. 22 is a vertical cross-sectional view of the exemplary bonded assembly after optional removal of a carrier substrate from the memory die according to an embodiment of the present disclosure.

FIG. 23 is a vertical cross-sectional view of the exemplary bonded assembly after formation of backside via openings according to an embodiment of the present disclosure.

FIG. 24 is a vertical cross-sectional view of the exemplary bonded assembly after formation of source connection structures and source-level metal interconnect structures according to an embodiment of the present disclosure.

FIG. 25A is a vertical cross-sectional view of the exemplary bonded assembly after formation of memory-die backside insulating layers and memory-die backside bonding structures according to an embodiment of the present disclosure.

FIG. 25B is a top-down view of the exemplary bonded assembly of FIG. 25A.

FIG. 26 is a vertical cross-sectional view of the exemplary bonded assembly after attaching a carrier substrate to the memory die according to an embodiment of the present disclosure.

FIG. 27 is a vertical cross-sectional view of the exemplary bonded assembly after thinning a controller-die semiconductor substrate according to an embodiment of the present disclosure.

FIG. 28 is a vertical cross-sectional view of the exemplary bonded assembly after formation of a controller-die backside dielectric layer according to an embodiment of the present disclosure.

FIG. 29 is a vertical cross-sectional view of the exemplary bonded assembly after formation of controller-die backside bonding structures according to an embodiment of the present disclosure.

FIG. 30 is a vertical cross-sectional view of the exemplary bonded assembly after attaching solder material portions to the controller-die backside bonding structures according to an embodiment of the present disclosure.

FIG. 31 is a vertical cross-sectional view of the exemplary bonded assembly after detaching the carrier substrate according to an embodiment of the present disclosure.

FIG. 32 is a vertical cross-sectional view of a first exemplary vertical stack of bonded assemblies according to an embodiment of the present disclosure.

FIG. 33 is a vertical cross-sectional view of a second exemplary vertical stack of bonded assemblies according to an embodiment of the present disclosure.

FIG. 34 is a vertical cross-sectional view of an alternative configuration of the first exemplary vertical stack of bonded assemblies according to an embodiment of the present disclosure.

FIG. 35 is a vertical cross-sectional view of an alternative configuration of the second exemplary vertical stack of bonded assemblies according to an embodiment of the present disclosure.

FIG. 36A is a vertical cross-sectional view of a first exemplary bonded assembly including a high bandwidth flash memory stack, a logic die, an interposer, and a packaging substrate according to an embodiment of the present disclosure. FIG. 36B is a vertical cross-sectional view of a second exemplary bonded assembly including a high bandwidth flash memory stack, a logic die, and a packaging substrate according to an embodiment of the present disclosure.

FIG. 37 is a vertical cross-sectional view of an alternative configuration of the exemplary bonded assembly after formation of a controller-die backside dielectric layer according to an embodiment of the present disclosure.

FIG. 38 is a vertical cross-sectional view of the alternative configuration of the exemplary bonded assembly after formation of controller-die backside bonding structures according to an embodiment of the present disclosure.

FIG. 39 is a vertical cross-sectional view of the alternative configuration of the exemplary bonded assembly after detaching the carrier substrate according to an embodiment of the present disclosure.

FIG. 40 is a vertical cross-sectional view of a third exemplary vertical stack of bonded assemblies according to an embodiment of the present disclosure.

FIG. 41 is a vertical cross-sectional view of a fourth exemplary vertical stack of bonded assemblies according to an embodiment of the present disclosure.

FIG. 42 is a vertical cross-sectional view of an alternative configuration of the third exemplary vertical stack of bonded assemblies according to an embodiment of the present disclosure.

FIG. 43 is a vertical cross-sectional view of an alternative configuration of the fourth exemplary vertical stack of bonded assemblies according to an embodiment of the present disclosure.

### DETAILED DESCRIPTION

As discussed above, the embodiments of the present disclosure are directed to a high bandwidth flash memory containing a stack of bonded logic and memory die assemblies and methods for manufacturing the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁻⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

According to an aspect of the present disclosure, a stack of multiple logic and memory die bonded assemblies can be constructed using through-substrate via (TSV) structures, which are also referred to as through-silicon via structures for silicon substrates. The logic dies may comprise memory-controller dies which control the respective memory die that is bonded to the respective memory-controller die in the same bonded assembly. The memory dies may comprise flash memory dies, such as flash memory dies containing three-dimensional NAND or NOR memory devices. The bonded assemblies may then be stacked and bonded to each other using TSVs and bonding pads on opposing sides of each bonded assembly. The stack of bonded assemblies provide increased bandwidth and memory capacity.

Metal-to-metal bonding can be employed between each bonded pair of a memory die and a memory-controller die, which constitutes a bonded assembly. Through-substrate via structures can be formed in the memory-controller dies to provide vertically-extending signal paths through each controller-die semiconductor substrate. Through stack via structures can be employed in each memory die to provide electrically conductive paths through the level of an alternating stack of insulating layers and electrically conductive layers. Each memory die may comprise a respective memory-die backside dielectric layer embedding respective memory-die backside bonding structures. A metal-to-metal bonding or a solder-mediated bonding may be employed to bond vertically neighboring pairs of bonded assemblies. The bonded assemblies may be bonded to each other in a stack using chip to chip (i.e., assembly to assembly) bonding or wafer-to-wafer bonding to reduce production costs. The stack of multiple bonded assemblies of the embodiments of the present disclosure provides a high bandwidth bonded flash memory chip array at a low manufacturing cost.

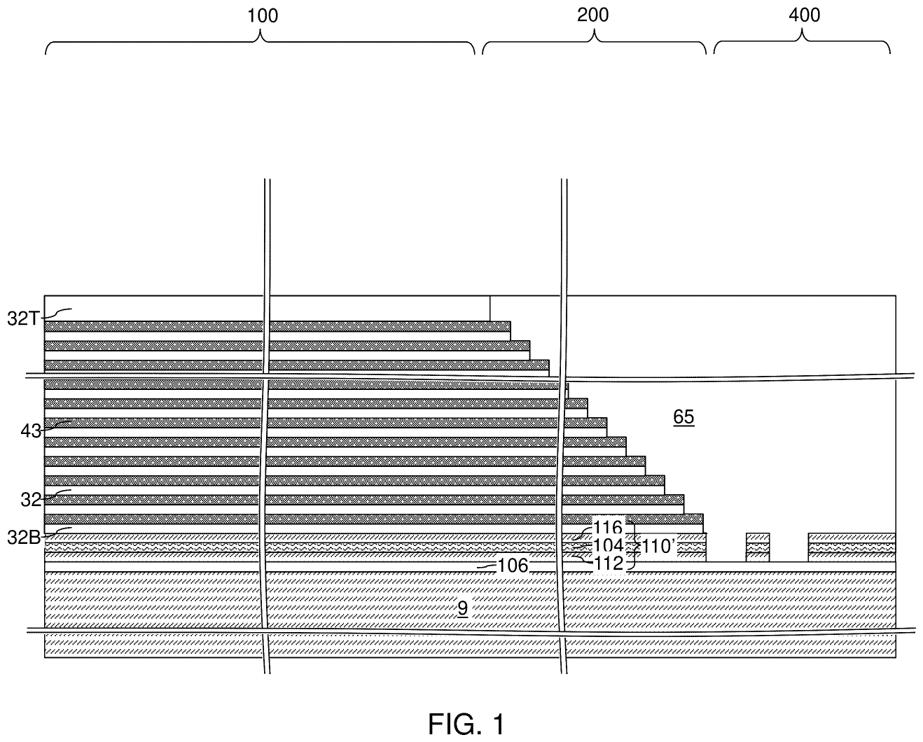

Referring to FIG. 1, a first exemplary structure according to an embodiment of the present disclosure is illustrated. The first exemplary structure comprises a carrier substrate 9, which may be a semiconductor substrate, a dielectric substrate, or a conductive substrate. For example, the carrier substrate 9 may comprise a commercially available silicon wafer. Alternatively, the carrier substrate 9 may comprise any material that may be removed selectively to the materials of a topmost memory-die backside dielectric layer 106 and a retro-stepped dielectric material portion 65 to be subsequently formed.

A dielectric material layer can be formed on a top surface of the carrier substrate 9. The dielectric material layer can be subsequently employed as a stopping material layer for a process that removes the carrier substrate 9, and is herein referred to as a topmost memory-die backside dielectric layer 106, or as a stopper dielectric layer. If a polishing process such as a chemical mechanical polishing process is employed to subsequently remove the carrier substrate 9, the topmost memory-die backside dielectric layer 106 may be subsequently employed as a polishing stopper material layer. If an etch process such as a wet etch process is employed to subsequently remove the carrier substrate 9, the topmost memory-die backside dielectric layer 106 may be subsequently employed as an etch stop material layer. In one embodiment, the topmost memory-die backside dielectric layer 106 comprises a dielectric material such as undoped silicate glass, a doped silicate glass, or silicon nitride. The thickness of the topmost memory-die backside dielectric layer 106 may be in a range from 50 nm to 600 nm, such as from 100 nm to 300 nm, although lesser and greater thicknesses may also be employed.

In-process source-level material layers 110′ can be formed over the topmost memory-die backside dielectric layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selectively to the lower sacrificial liner (or selective to the lower source-level semiconductor layer 112) and the upper sacrificial liner (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the topmost memory-die backside dielectric layer 106 may be omitted, and the alternating stack is formed directly on a surface of the carrier substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The first exemplary structure comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

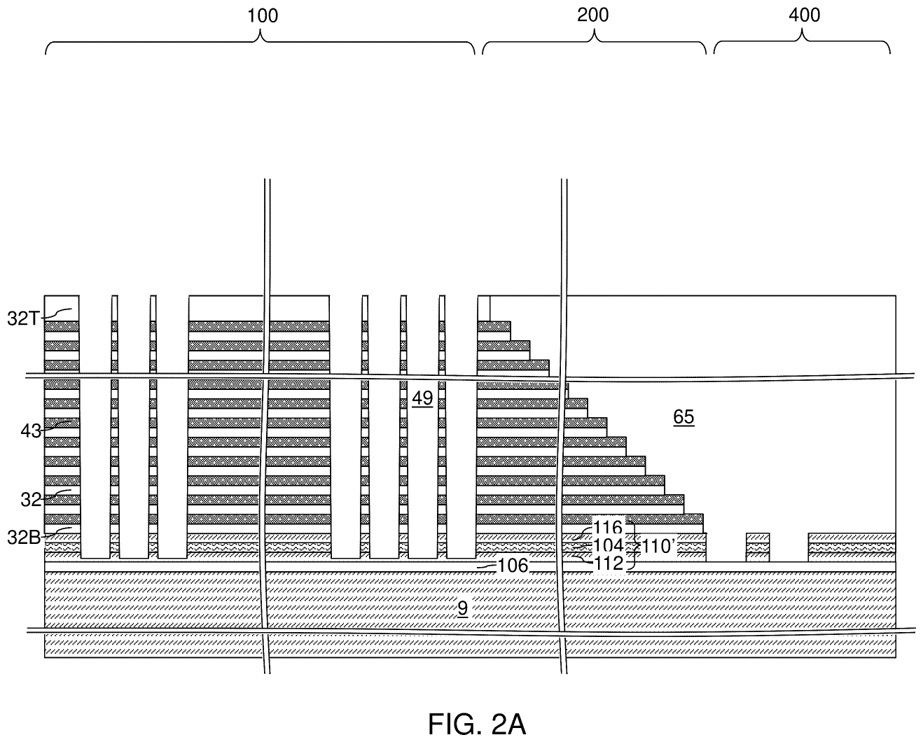

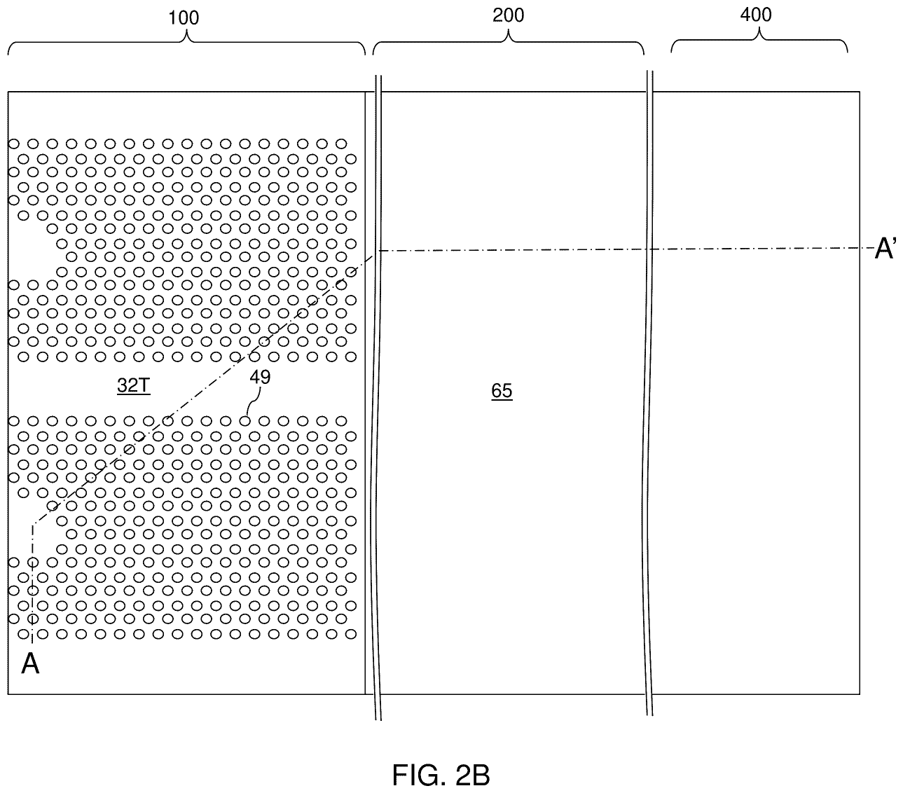

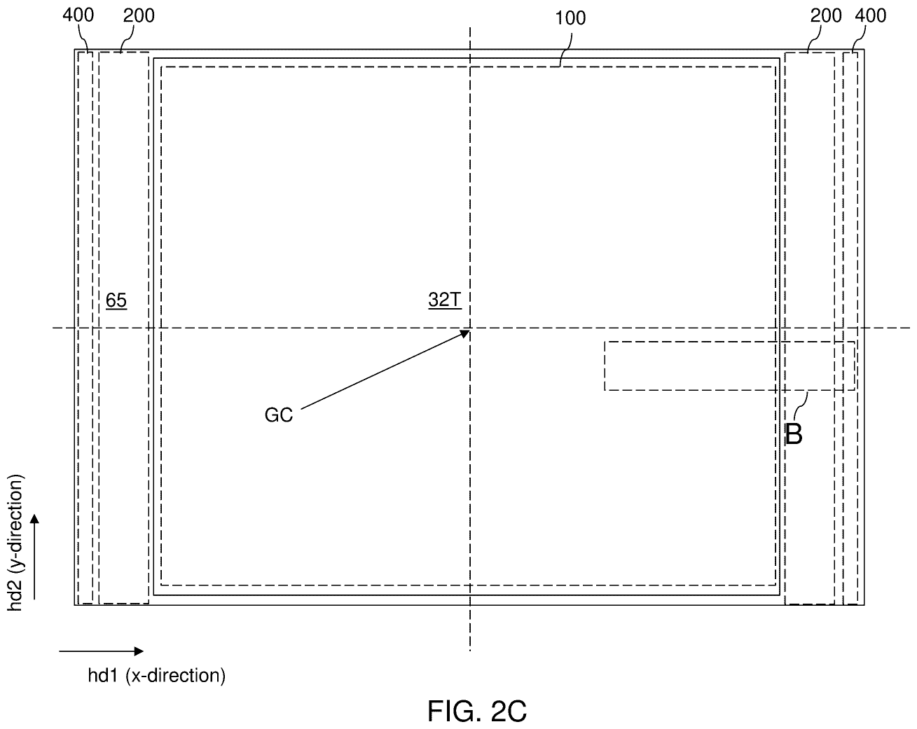

Referring to FIGS. 2A-2C, various views of the first exemplary structure are illustrated after formation of memory openings 49. FIG. 2C is a top-down view of the first exemplary structure that illustrates an entire area of an in-process memory die. FIG. 2B is a top-down view of region B of the top-down view of the first exemplary structure shown in FIG. 2C. FIG. 2A is a vertical cross-sectional view of the first exemplary structure along the vertical plane A-A′ of FIG. 2B. The in-process memory die may have a rectangular shape in a plan view, such as the top-down view of FIG. 2C. The geometrical center GC of the in-process memory die is also illustrated in FIG. 2C. As used herein, a geometrical center of an element refers to a center of gravity of a hypothetical object occupying the same volume as the element and having a uniform density throughout.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′ In one embodiment, bottom surfaces of the memory openings 49 and the support openings may be formed within the lower source-level semiconductor layer 112 or at an interface between the lower source-level semiconductor layer and the topmost memory-die backside dielectric layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or a polymer material. A dielectric fill material can be deposited in the support openings to form support pillar structures (not shown). The sacrificial memory opening fill structures can be subsequently removed to form cavities in the memory openings 49.

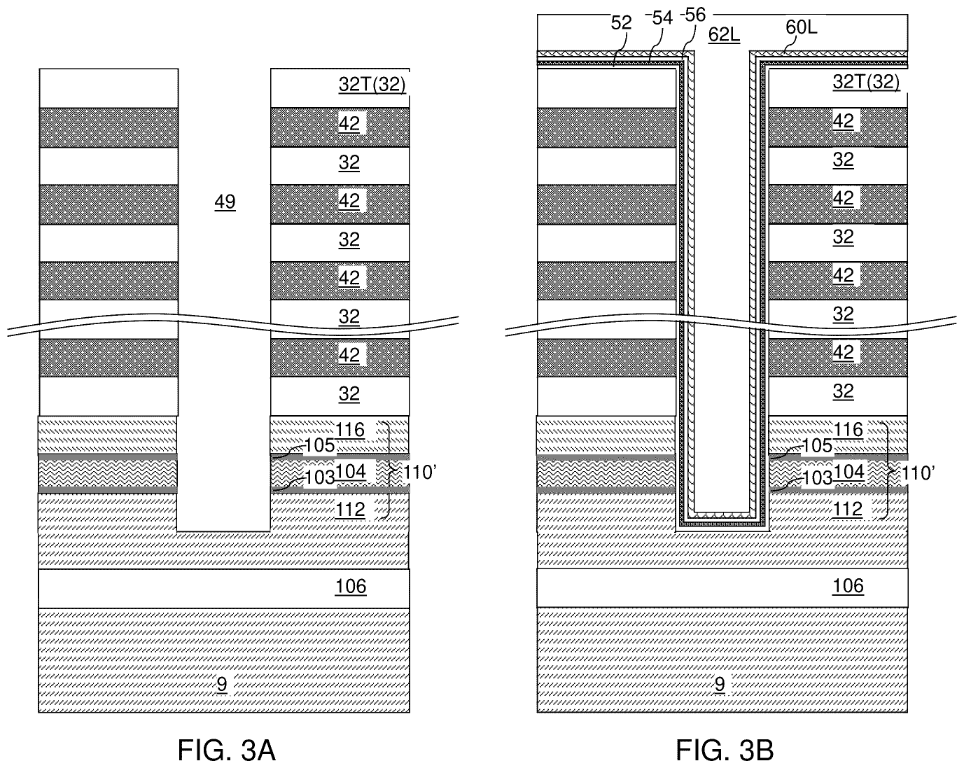

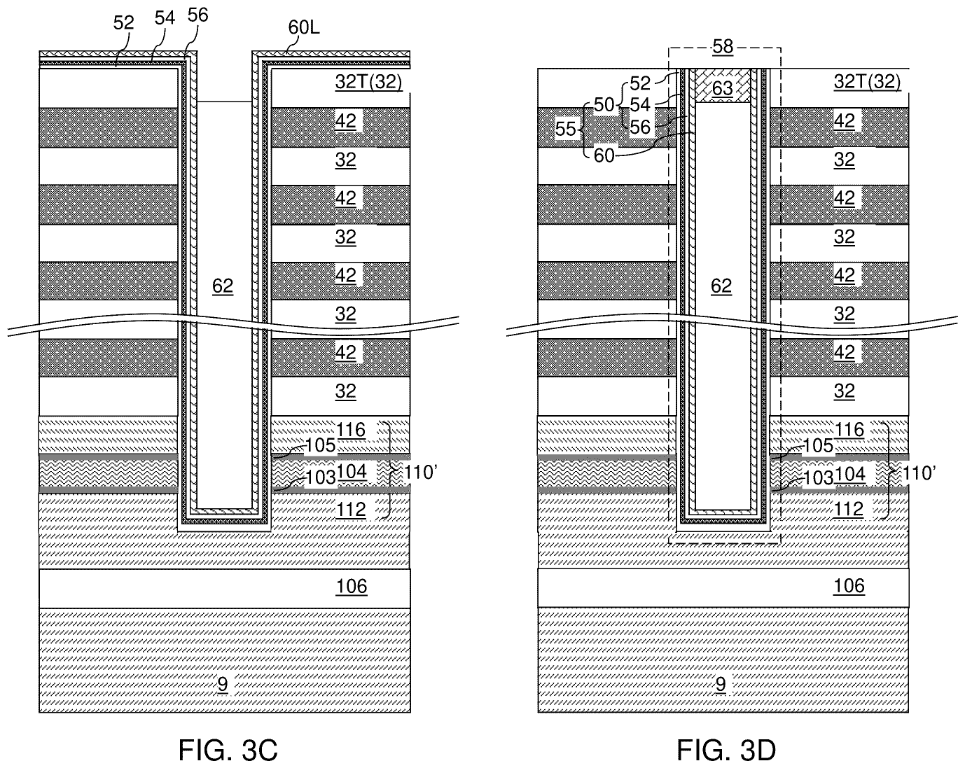

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C.

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

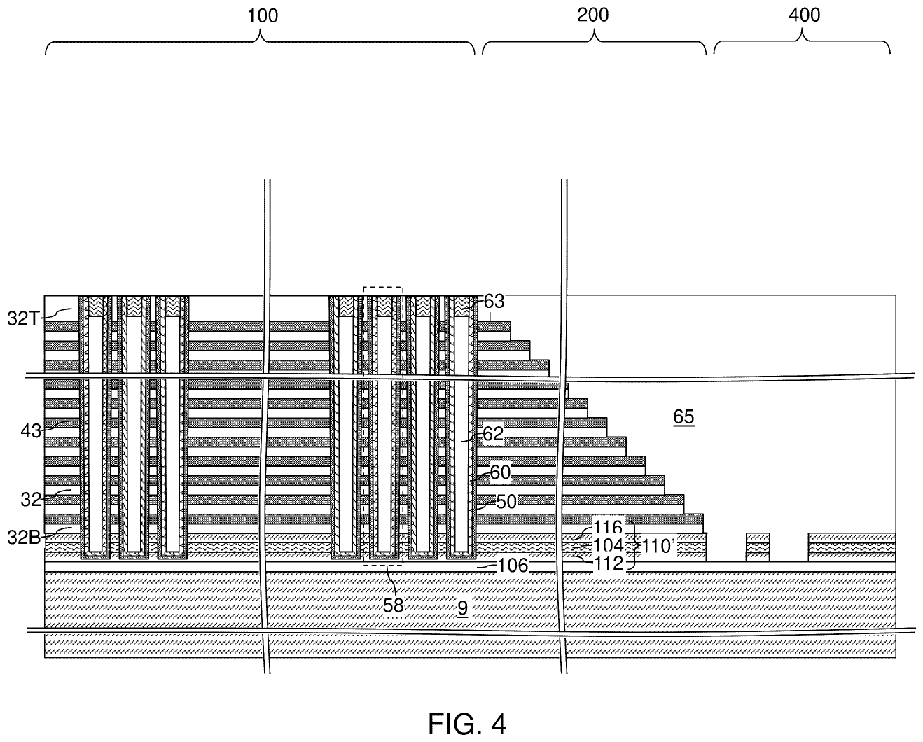

Referring to FIG. 4, the first exemplary structure is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

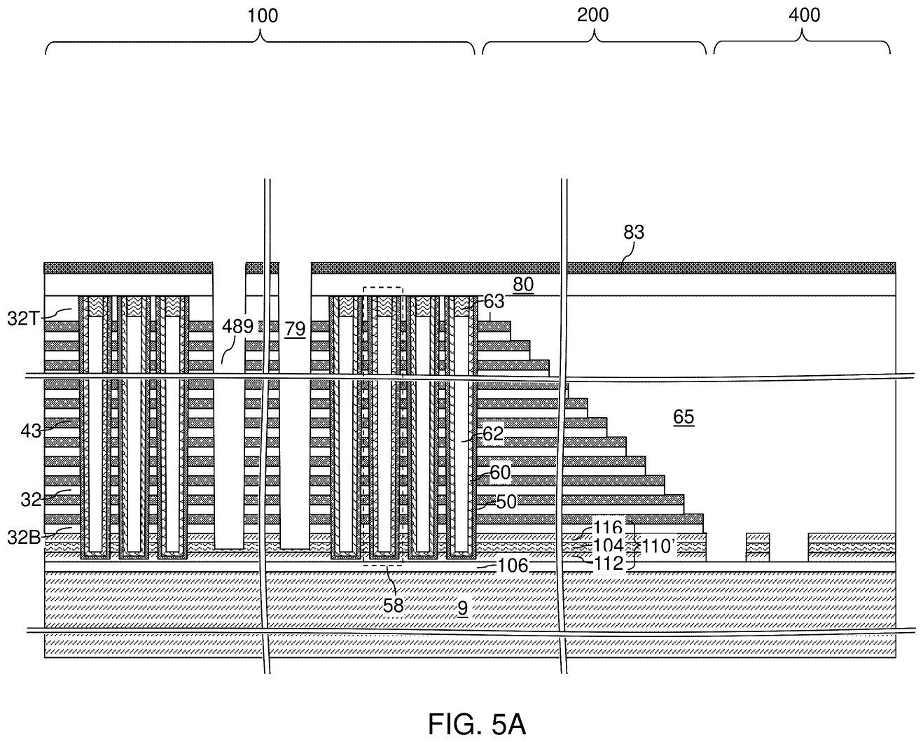

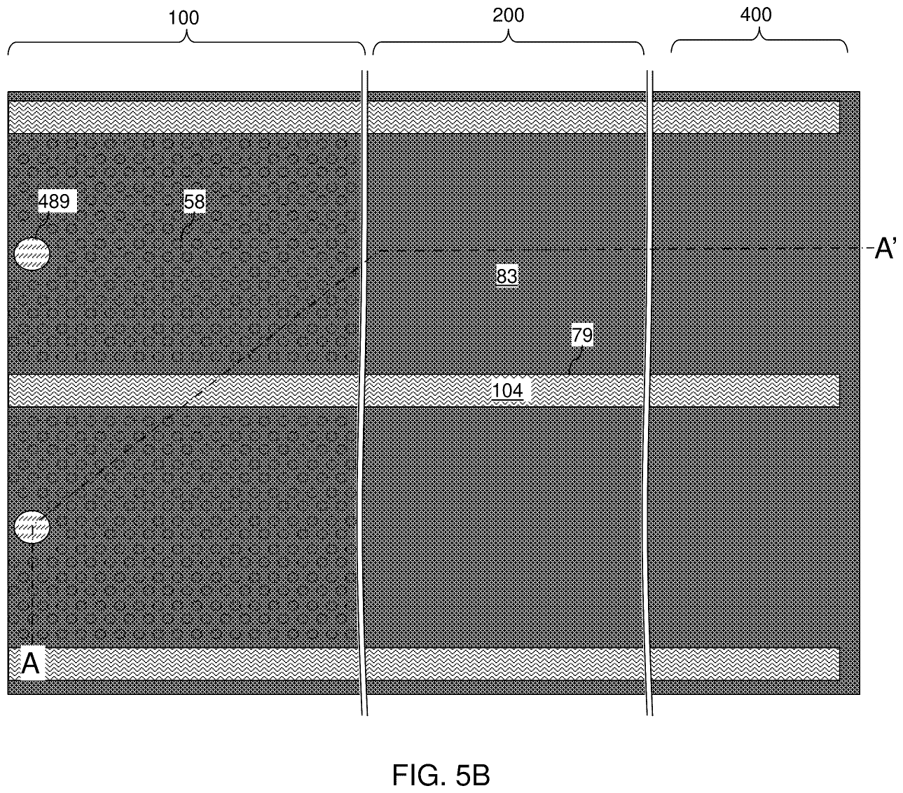

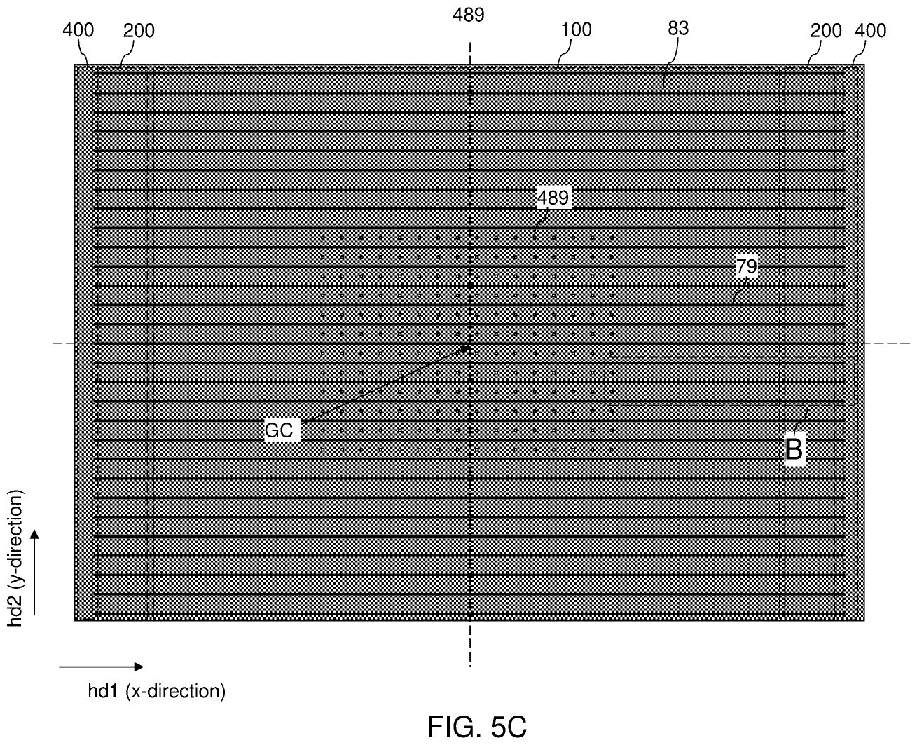

Referring to FIGS. 5A-5C, various views of the exemplary are illustrated after formation of a contact-level dielectric layer 80, a patterned hard mask layer 83, lateral isolation trenches 79, and through-stack openings 489. FIG. 5C is a top-down view of the first exemplary structure that illustrates an entire area of an in-process memory die. FIG. 5B is a top-down view of region B of the top-down view of the first exemplary structure shown in FIG. 5C. FIG. 5A is a vertical cross-sectional view of the first exemplary structure along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110′. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 489 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 489 may comprise surface segments of the source-level sacrificial layer 104. In one embodiment, the through-stack openings 489 may be arranged as a two-dimensional periodic array. In one embodiment, the through-stack openings 489 may be formed in a center region of the in-process memory die in a plan view. In one embodiment, peripheral regions of the in-process memory die may be free of any through-stack openings 489.

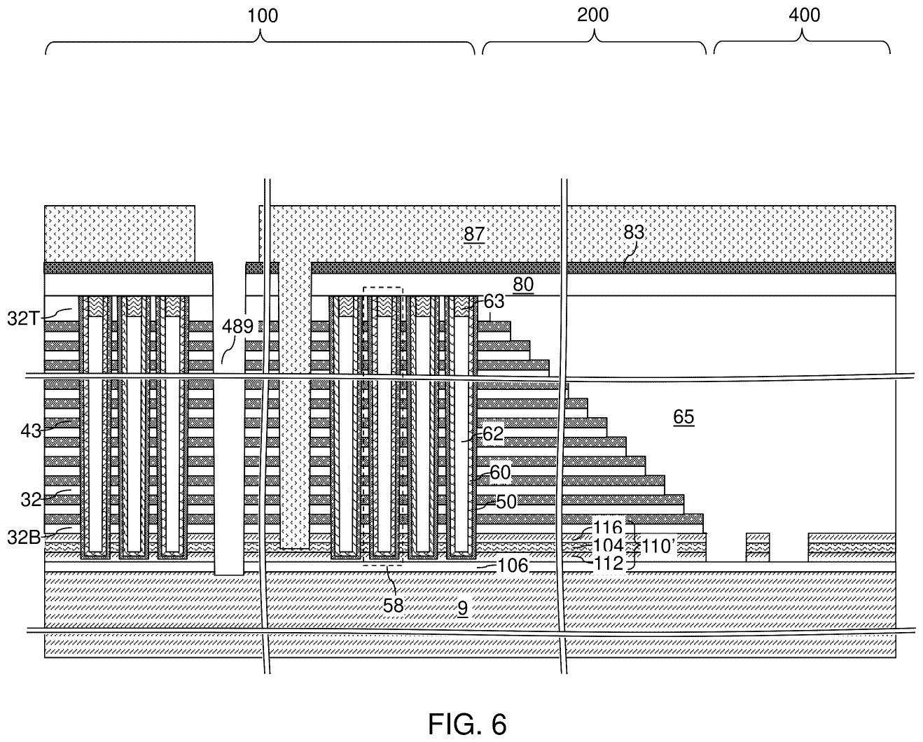

Referring to FIG. 6, a photoresist layer 87 can be applied over the first exemplary structure, and can be lithographically patterned to form openings around the through-stack openings 489. The photoresist layer 87 can cover all areas of the lateral isolation trenches 79. An anisotropic etch process can be performed to vertically extend the through-stack openings 489 through the in-process source-level material layers 110′ and the topmost memory-dic backside dielectric layer 106 and optionally into an upper portion of the carrier substrate 9. The photoresist layer 87 can be subsequently removed, for example, by ashing. The patterned hard mask layer 83 can be removed selectively to the contact-level dielectric layer, for example, by performing a wet etch process.

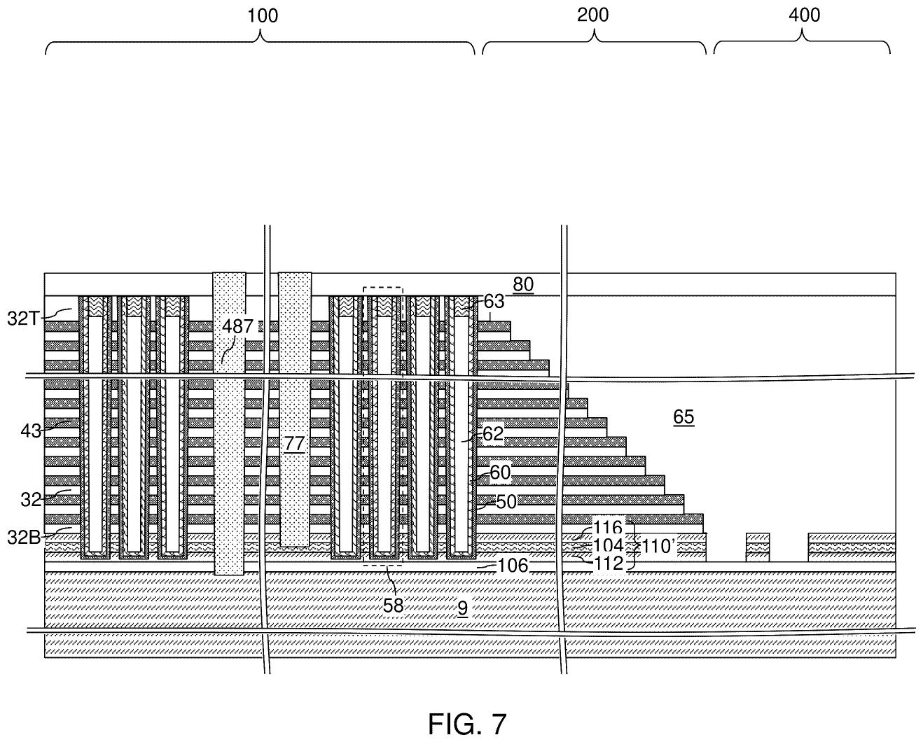

Referring to FIG. 7, a sacrificial fill material can be deposited in the lateral isolation trenches 79 and the through-stack openings 489. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 489 constitute sacrificial through-stack opening fill structures 487.

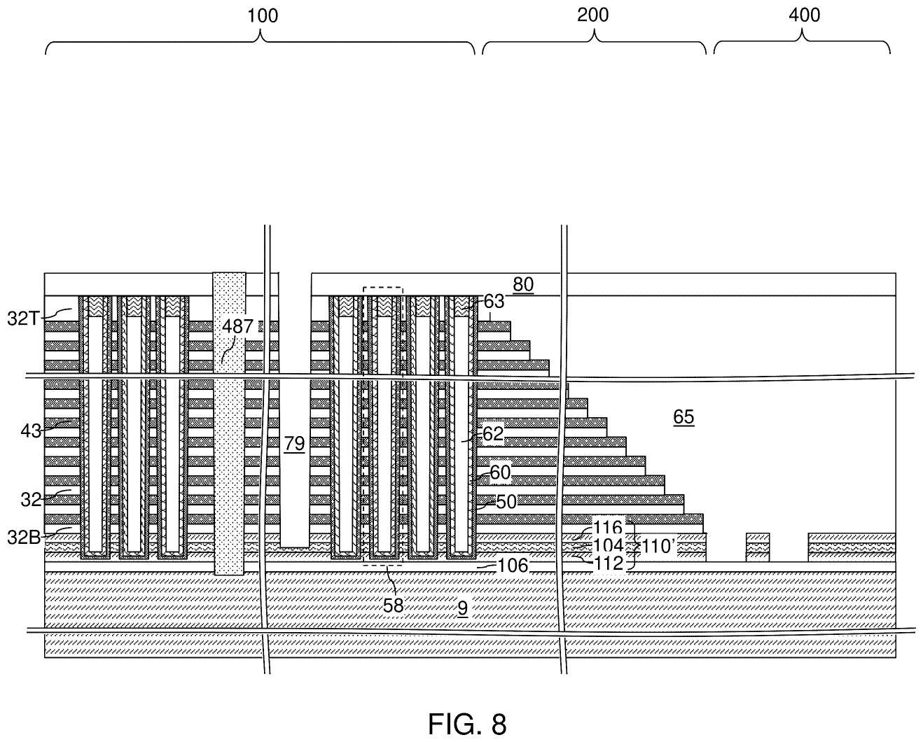

Referring to FIG. 8, a photoresist layer (not shown) can be applied over the contact-level dielectric layer 80, and can be lithographically patterned to cover the sacrificial through-stack opening fill structures 487 without covering the sacrificial lateral isolation trench fill structures 77. The sacrificial lateral isolation trench fill structures 77 can be removed selectively to the materials of the contact-level dielectric layer 80 and the alternating stack (32, 42) to form cavities within the volumes of the lateral isolation trenches 79 (i.e., to reopen the lateral isolation trenches 79).

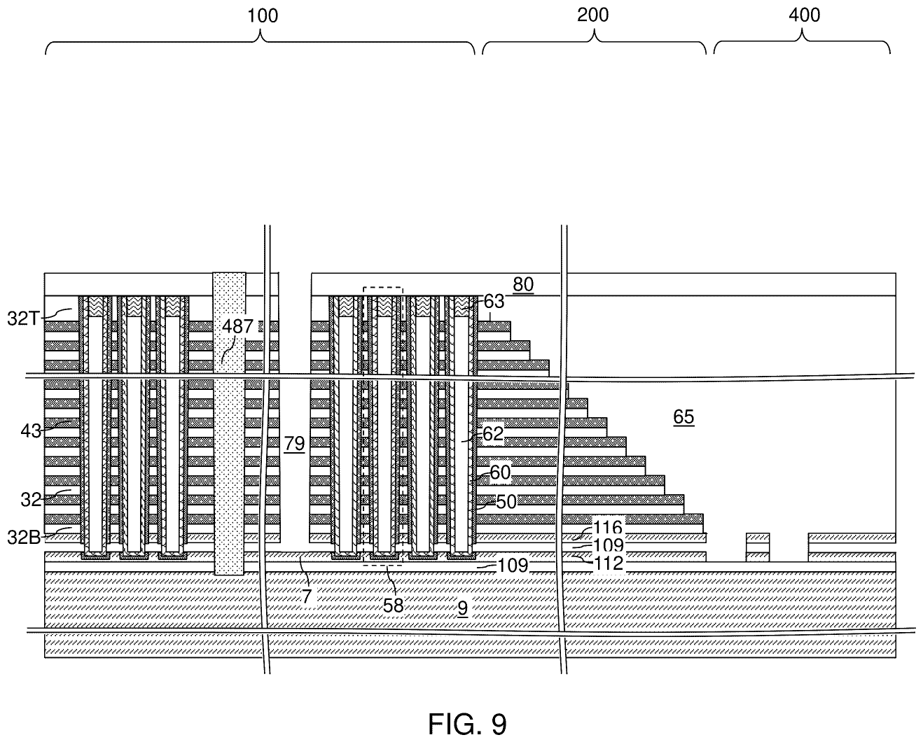

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the first exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

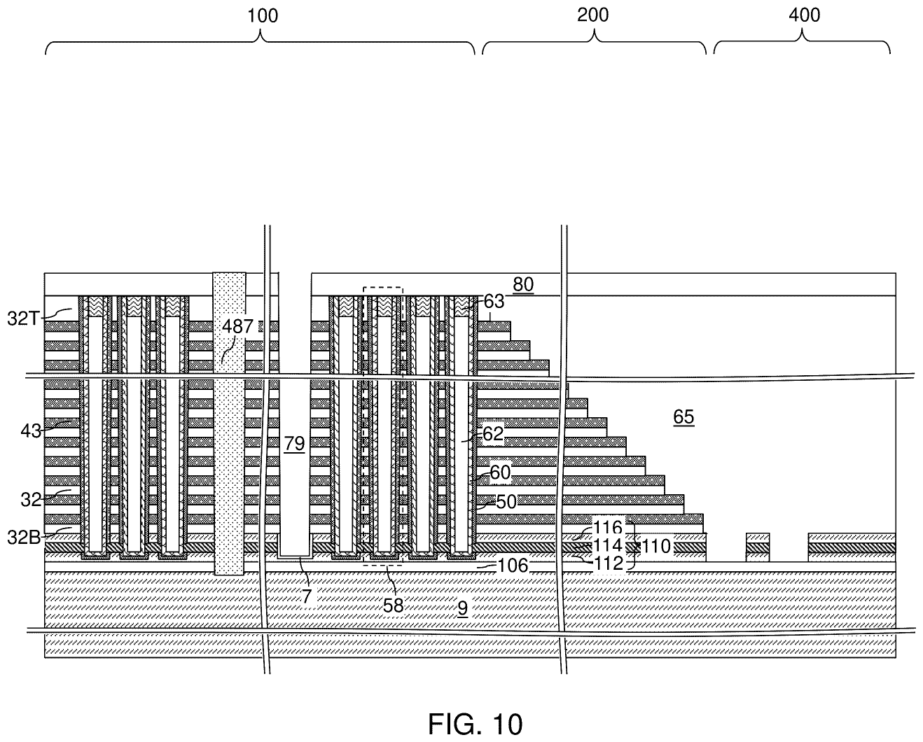

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source layer 110, which replaces the in-process source-level material layers 110′. The source layer 110 contacts a sidewall surface segment of each of the vertical semiconductor channels 60. An oxidation process can be performed to convert physically exposed portions of the semiconductor material layer around bottom portions of the lateral isolation trenches 79. A semiconductor oxide liner 7, such as a silicon oxide liner, can be formed at the bottom of each lateral isolation trench 79.

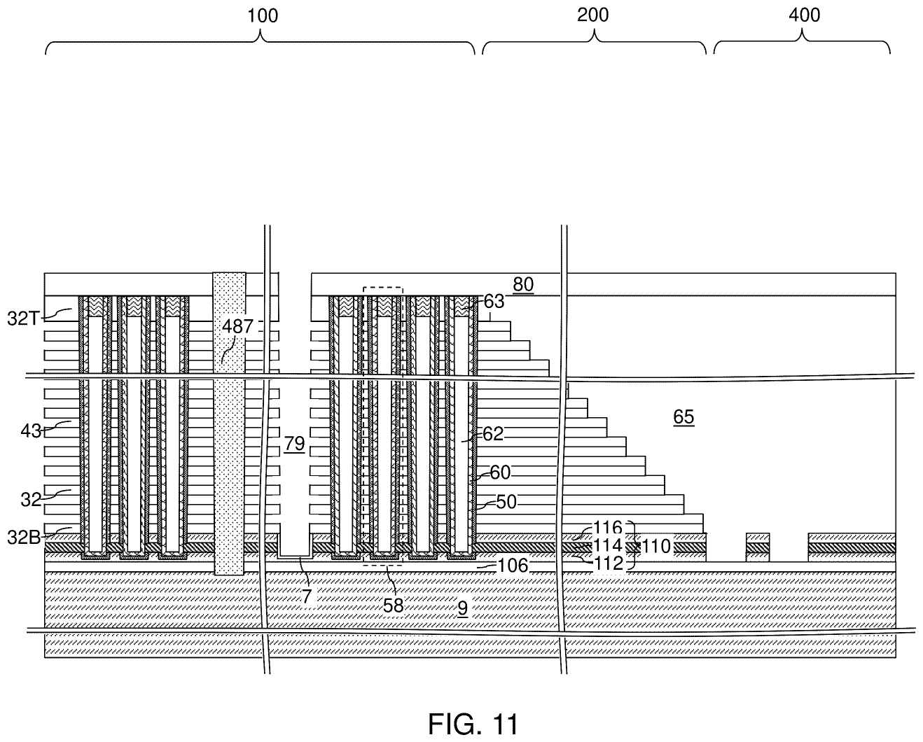

Referring to FIG. 11, an isotropic etch process can be performed to remove the sacrificial material layers 42 selective to the insulating layers 32, the semiconductor oxide liners 7, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the first exemplary structure is immersed in phosphoric acid at or near the boiling point of the phosphoric acid. A suitable clean process may be performed as needed. In summary, the laterally-extending cavities 43 can be formed by removing the sacrificial material layers 42 selective to the insulating layers 32 and the memory opening fill structures 58.

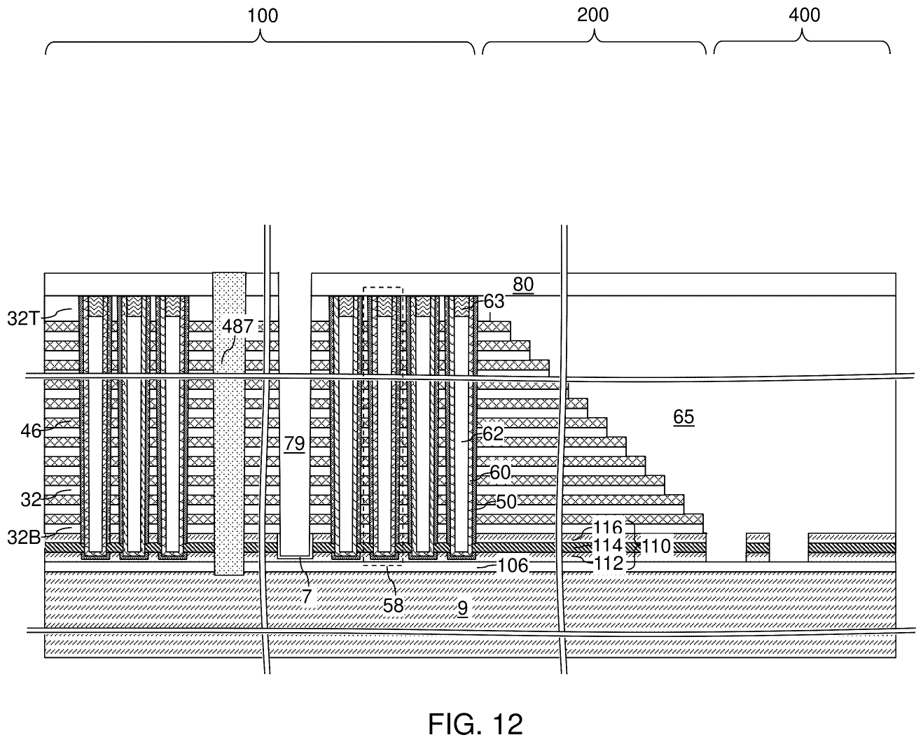

Referring to FIG. 12, a backside blocking dielectric layer (not shown) may be optionally is deposited in the laterally-extending cavities 43. The backside blocking dielectric layer, if employed, includes and/or consists essentially of a dielectric metal oxide material. At least one metallic material can be conformally deposited in the laterally-extending cavities 43. The at least one metallic material may comprise a combination of a metallic nitride barrier material and a metallic fill material. For example, the metallic nitride barrier material may comprise TiN, TaN, WN, or MON, and the metallic fill material may comprise W, Ru, Mo, Co, etc.

An anisotropic etch process can be performed to remove portions of the at least one metallic material and optionally the backside blocking dielectric layer from inside the volumes of the lateral isolation trenches 79 and from above the contact-level dielectric layer 80. Each contiguous remaining portion of the at least one metallic material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

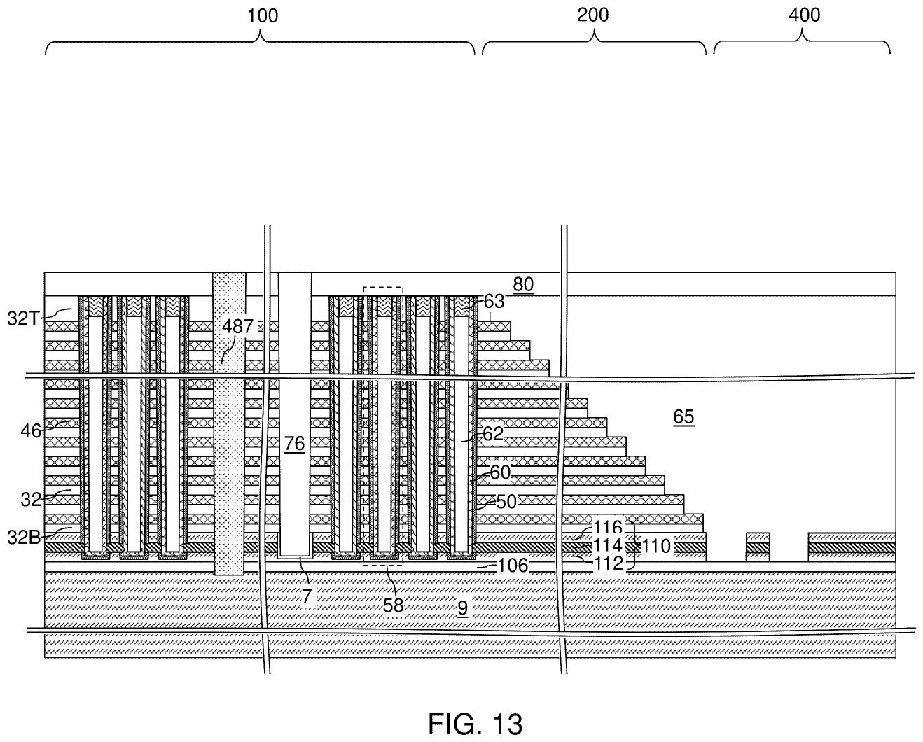

Referring to FIG. 13, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer. In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to another horizontal plane including a topmost surface of the alternating stack (32, 46).

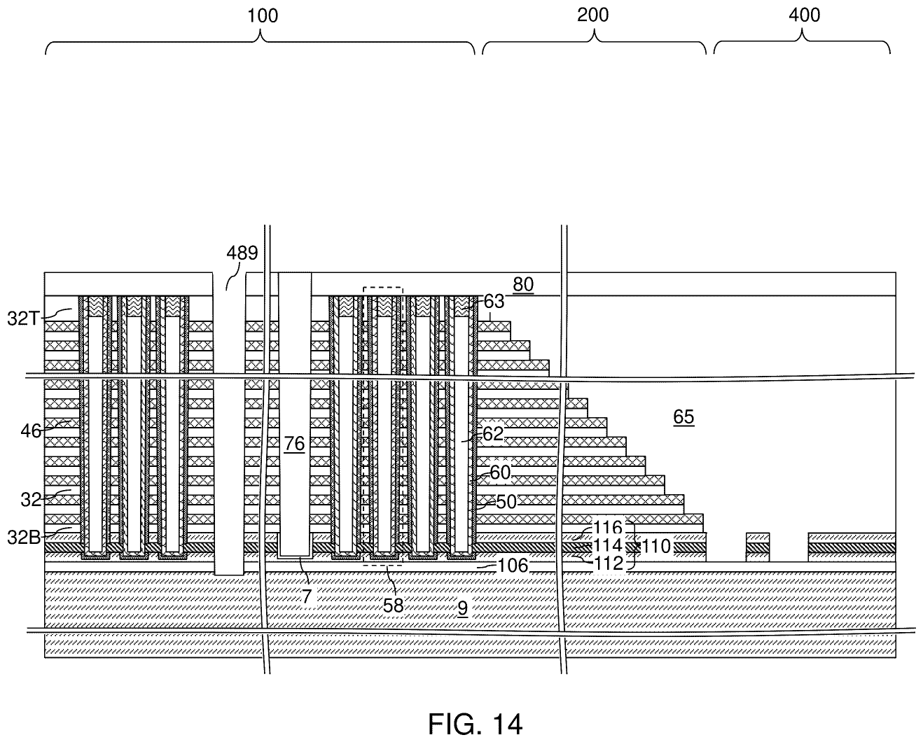

Referring to FIG. 14, a selective etch process can be performed to remove the sacrificial through-stack opening fill structures 487 selective to the materials of the contact-level dielectric layer 80 and the alternating stacks (32, 42). Cavities are formed in the volumes of the through-stack openings 489.

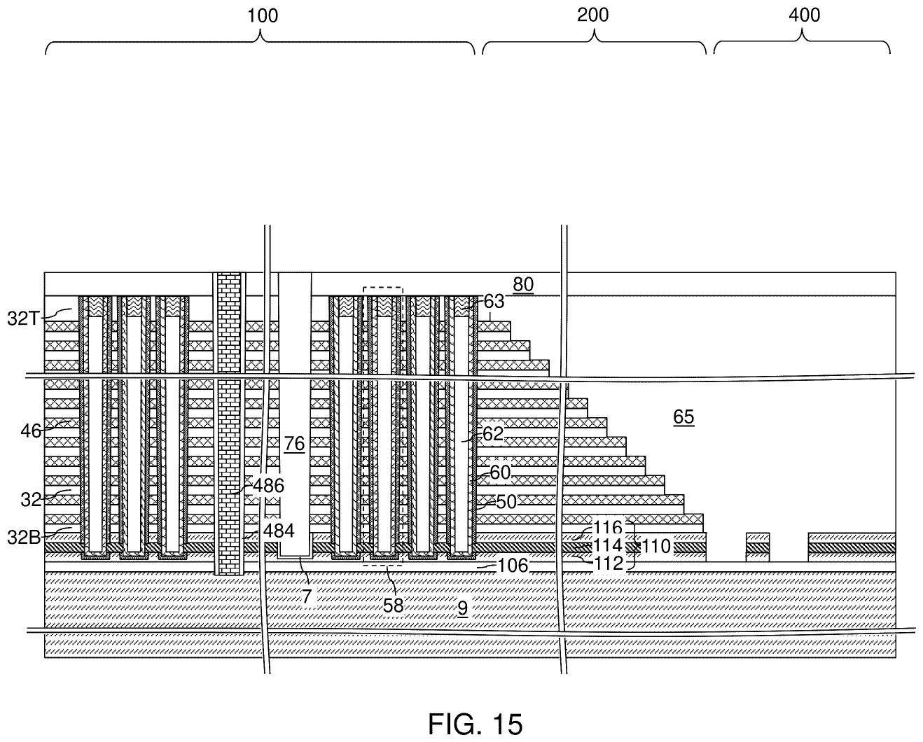

Referring to FIG. 15, a dielectric material, such as silicon oxide, can be conformally deposited in peripheral portions of the through-stack openings 489. An anisotropic etch process can be performed to remove horizontally-extending portions of the deposited dielectric material. Each remaining tubular portion of the deposited dielectric material located in peripheral regions of the through-stack openings 489 constitutes a tubular dielectric spacer 484. The lateral thickness of each tubular dielectric spacer 484 (as measured between an inner sidewall and an outer sidewall) may be in a range from 30 nm to 100 nm, although lesser and greater thicknesses may also be employed.

At least one conductive material, such as at least one metallic material, can be deposited in center regions of the through-stack openings 489. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 489 comprises a through-stack via structure 486.

The through-stack via structures 486 are formed in a center region of the in-process memory die. As used herein, the center region is defined as a volume within the in-process memory die that is more proximal to the geometrical center GC of the in-process memory die than to a periphery of the in-process memory die. The periphery is defined by the outer boundary of the in-process memory die in a plan view along a vertical direction.

In one embodiment, at least one of the vertically-extending openings 489 in the alternating stacks (32, 46) is entirely laterally surrounded by a respective one of the alternating stacks (32, 46). In one embodiment, the entirety of at least one of the vertically-extending openings 489 may be located within the area of a respective one of the alternating stacks (32, 46) in the plan view. In one embodiment, at least one of the through-stack via structures 486 is located within a respective one of the vertically-extending openings 489, and is laterally spaced from a sidewall of the respective one of the vertically-extending opening 489 by a respective tubular dielectric spacer 484.

In one embodiment, sidewalls of the through-stack openings 489 may be tapered such that each through-stack opening 489 has a greater lateral dimension at its top than at its bottom. In one embodiment, sidewalls of the through-stack via structures 486 are tapered relative to a vertical direction such that each of the through-stack via structures 486 has a respective variable horizontal cross-sectional area that increases with a vertical distance from the carrier substrate 9.

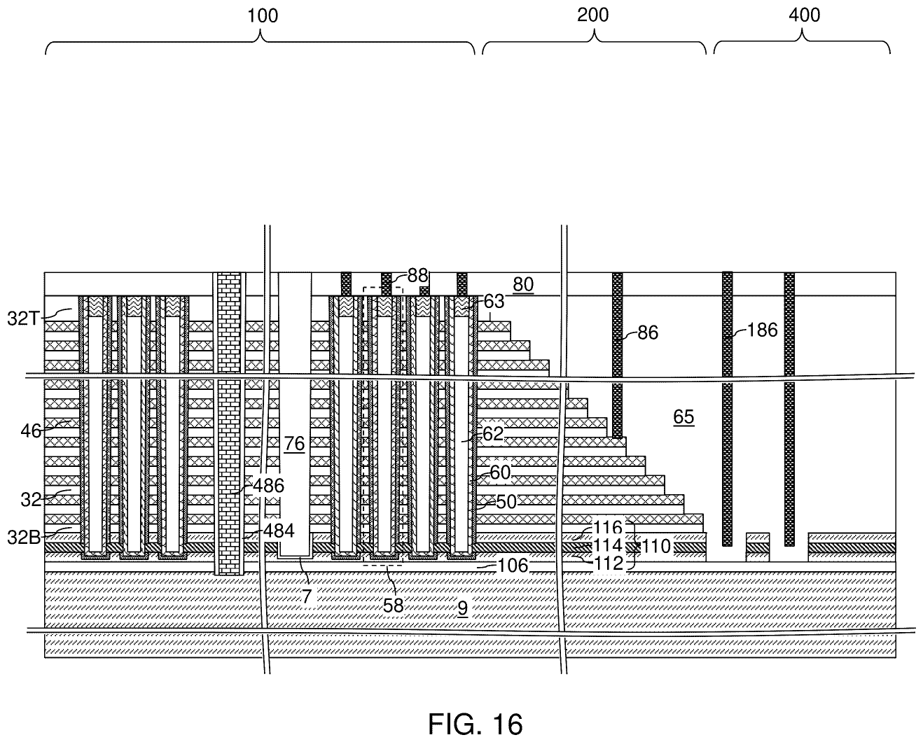

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities constitute peripheral connection via structures 186.

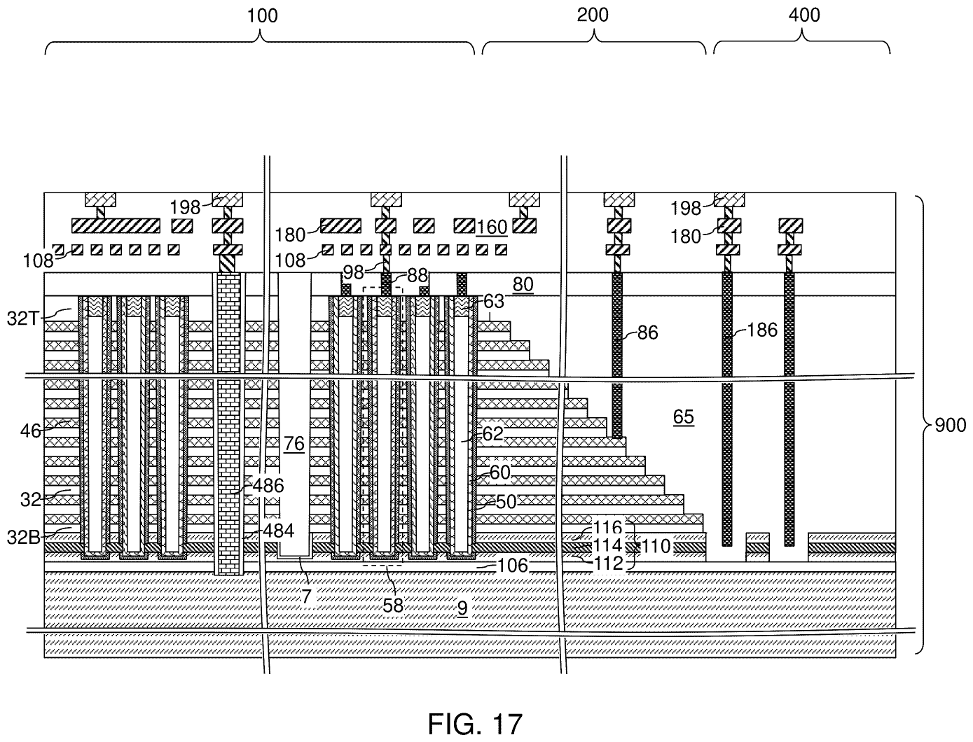

Referring to FIG. 17, additional dielectric material layers embedding metal interconnect structures can be formed over the contact-level dielectric layer 80. The additional dielectric material layers are herein referred to as memory-die front dielectric material layers 160. The metal interconnect structures are herein referred to as memory-die metal interconnect structures (98, 108, 180). The memory-die metal interconnect structures (98, 108, 180) may include bit lines 108 that laterally extend along the second horizontal direction hd2, bit-line-connection via structures 98 that connect the drain contact via structures 88 with the bit lines 108, and additional metal interconnect structures 180 which include various types of metal via structures and various types of metal lines.

Memory-die front bonding structures 198 configured for metal-to-metal bonding can be formed in the topmost dielectric layer of the memory-die front dielectric material layers 160. Metal-to-metal bonding involves direct attachment of contacting metal surfaces to each other without use of any intermediate material. As used herein, “metal-to-metal bonding” refers to the process of directly joining metal surfaces without any intervening adhesive or bonding layer. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-die front bonding structures 198 may have physically exposed copper surfaces.

The first exemplary structure comprises a memory die 900. In one embodiment, a two-dimensional array of memory dies 900 may be formed on the same carrier substrate 9. For example, the carrier substrate 9 may comprise a commercially available silicon wafer, and the two-dimensional array of memory dies 900 may comprise a periodic rectangular array of memory dies 900 comprising a respective portion of the silicon wafer and the overlying device layers.

Generally, a plurality of memory dies 900 can be provided. Each of the plurality of memory dies 900 may comprise: an alternating stack (32, 46) of insulating layers 32 and electrically conductive layers 46 that alternate along a vertical direction; a two-dimensional array of memory stack structures 55 each containing a respective vertical semiconductor channel 60 and respective vertical stack of memory elements (comprising portions of the memory material layer 54); and through-stack via structures 486 vertically extending at least from a horizontal plane including a bottommost surface of the alternating stack (32, 46) to another horizontal plane including a topmost surface of the alternating stack (32, 46).

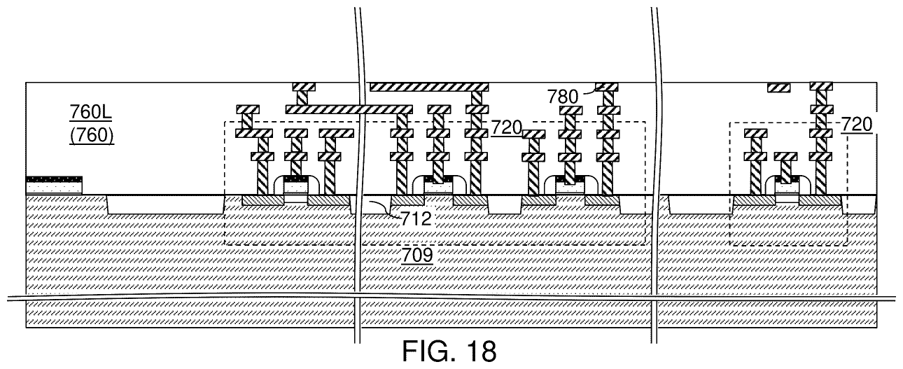

Referring to FIG. 18, a second exemplary structure including an in-process memory-controller die is illustrated. The in-process memory-controller die may be provided within a unit area in a substrate, such as a semiconductor (e.g., silicon) wafer including a two-dimensional array of in-process memory-controller dies. The in-process memory-controller die comprises a substrate, such as a semiconductor substrate 709, which is also referred to as a logic-die semiconductor substrate. The semiconductor substrate 709 may comprise a silicon wafer. Shallow trench isolation structures 712 can be formed in an upper portion of the semiconductor substrate 709. A memory controller circuit 720, which is also referred to as a peripheral circuit or driver circuit, can be formed on and/or over the top surface of the semiconductor substrate 709.

The memory controller circuit 720 is configured to control operation of the memory array within the memory die 900. For example, the memory controller circuit 720 may comprise word line drivers configured to drive word lines, which are a subset of the electrically conductive layers 46 within the alternating stacks (32, 46). The memory controller circuit 720 may comprise bit line drivers configured to drive the bit lines 108 in the memory die 900. For example, as described with reference to the memory die 900, the bit lines 108 of a memory die 900 may be electrically connected to first ends (i.e., the ends that are connected to the drain regions 63) of a respective subset of the memory stack structures 55. The memory controller circuit 720 may comprise source line drivers configured to drive one or more source layers to be subsequently formed on the memory die 900 after removal of the carrier substrate 9. The memory controller circuit 720 may also comprise input/output control circuits configured to receive input data from, or to transmit output data to, at least one conductive pad (which may be a bonding structure) to be subsequently formed on the through-stack via structures 486 after removal of the carrier substrate 9. Generally, the memory controller circuit 720 may comprise any electronic circuit configured to manage data flow, handle read and write operations, ensure data integrity through error correction, perform wear leveling to extend memory lifespan, and/or support communication protocols for interfacing with external devices and systems for the three-dimensional memory array in the memory die 900.

Controller-die front metal interconnect structures 780 embedded within controller-die front dielectric material layers 760 can be formed over the memory controller circuit 720. Specifically, a first subset of the controller-die front metal interconnect structures 780 embedded within a first subset of the controller-die front dielectric material layers 760 can be formed. The first subset of the controller-die front dielectric material layers 760 is herein referred to as lower controller-die front dielectric material layers 760L. In the illustrated example in FIG. 18, the lower controller-die front dielectric material layers 760L comprise four via-level dielectric material layers and four line-level dielectric material layers. Generally, the total number of line levels within the lower controller-die front dielectric material layers 760L may be in a range from 1 to 12.

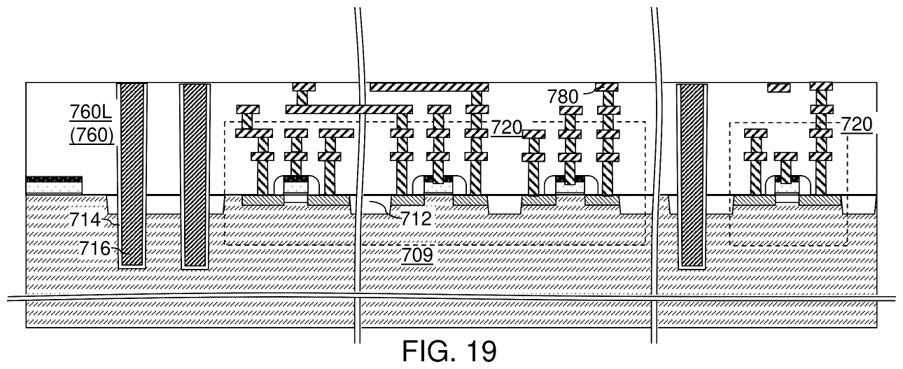

Referring to FIG. 19, a photoresist layer (not shown) can be applied over the top surface of the lower controller-die front dielectric material layers 760L, and can be lithographically patterned to form openings in areas that do not overlap with the controller-die front metal interconnect structures 780 that are embedded within the lower controller-die front dielectric material layers 760L. An anisotropic etch process can be performed to form via cavities that vertically extend through the lower controller-die front dielectric material layers 760L and an upper portion of the semiconductor substrate 709. Upon thinning of the semiconductor substrate 709 in a subsequent processing step, the via cavities vertically extend through the thinned semiconductor substrate 709, and as such, the via cavities are herein referred to as through-substrate via cavities. The depth of the bottom surfaces of the through-substrate via cavities, as measured from the horizontal plane including the top surface of the semiconductor substrate 709, may be in a range from 5 microns to 30 microns, although lesser and greater depths may also be employed. The photoresist layer can be subsequently removed, for example, by ashing.

A dielectric spacer material, such as silicon oxide, can be conformally deposited in peripheral regions of the through-substrate via cavities. A metallic fill material such as copper, tungsten, titanium, tantalum, and/or molybdenum may be deposited in remaining volumes of the through-substrate via cavities. Excess portions of the metallic fill material and the dielectric spacer material can be removed from above the horizontal plane including the top surface of the lower controller-die front dielectric material layers 760L. Each remaining portion of the dielectric spacer material comprises a dielectric spacer 714. The thickness of each dielectric spacer 714 may be in a range from 20 nm to 100 nm, although lesser and greater thicknesses may also be employed. Each remaining portion of the metallic fill material comprises a through-substrate via (TSV) structure 716, such as a through-silicon via structure. Each TSV structure 716 may have a respective top surface within a horizontal plane including top surfaces of a subset of the controller-die front metal interconnect structures 780, and may have a respective bottom surface located within a horizontal plane located between a top surface of the semiconductor substrate 709 and a bottom surface of the semiconductor substrate 709.

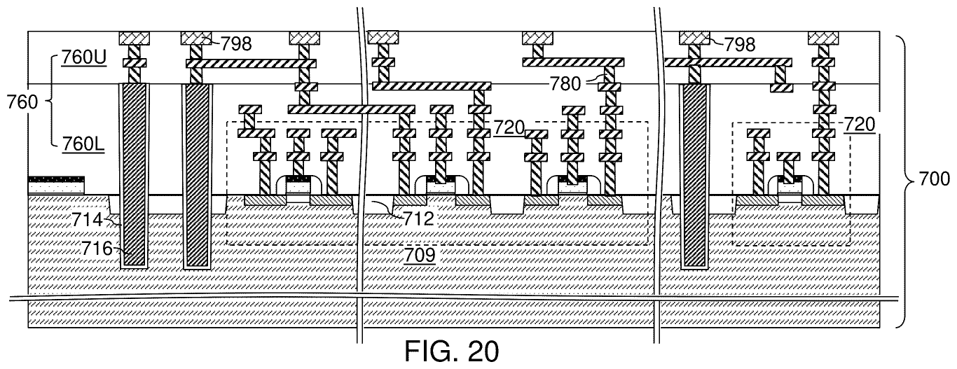

Referring to FIG. 20, a second subset of the controller-die front metal interconnect structures 780 embedded within a second subset of the controller-die front dielectric material layers 760 can be formed. The second subset of the controller-die front dielectric material layers 760 is herein referred to as upper controller-die front dielectric material layers 760U. In the illustrated example in FIG. 20, the upper controller-die front dielectric material layers 760U comprise a via-level dielectric material layer and two line-level dielectric material layers. Generally, the total number of line levels within the upper controller-die front dielectric material layers 760U may be in a range from 1 to 12.

Bonding structures configured for metal-to-metal bonding can be formed in the topmost layer among the controller-die front dielectric material layers 760. These bonding structures are herein referred to as controller-die front bonding structures 798. The controller-die front bonding structures 798 can be electrically connected to a respective electrical node of the memory controller circuit 720, and can be arranged in a pattern that is a mirror image pattern of the memory-die front bonding structures 198 of the memory die 900. A memory-controller die 700 can be provided. In one embodiment, the memory-controller die 700 may be provided within a unit die area in a semiconductor wafer including a two-dimensional array of memory controller-dies 700.

A plurality of memory-controller dies 700 may be provided. Each memory-controller die 700 comprises a respective semiconductor substrate 709, a respective memory controller circuit 720 including a respective set of semiconductor devices located on a front surface of the respective semiconductor substrate 709; respective controller-die front dielectric material layers 760 embedding respective controller-die front metal interconnect structures 780 and located on the respective set of semiconductor devices; respective controller-die front bonding structures 798 that are embedded within the controller-die front dielectric material layers 760; and respective TSV structures 716 that vertically extend through a subset of the respective controller-die front dielectric material layers 760 and an upper portion of the respective semiconductor substrate 709.

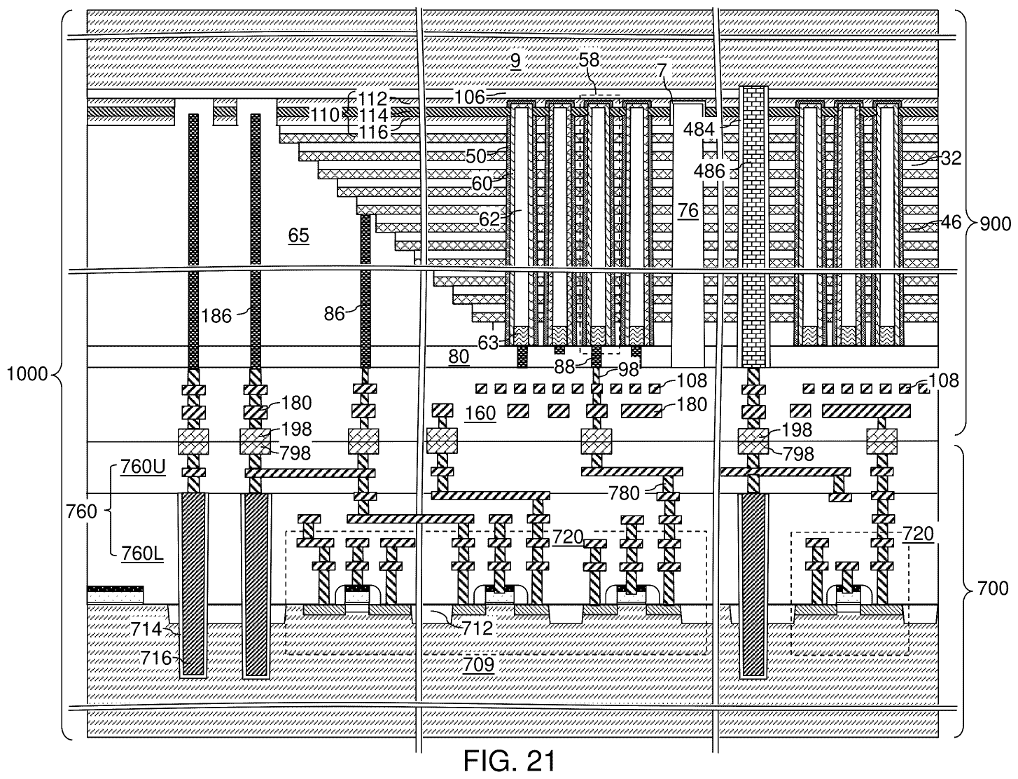

Referring to FIG. 21, a unit bonded assembly 1000 can be formed by bonding the memory-controller die 700 described with reference to FIG. 20 with the memory die 900 described with reference to FIG. 17. A plurality of unit bonded assemblies 1000 can be formed. Each of the plurality of unit bonded assemblies 1000 constitutes a bonded assembly 1000. The memory-controller die 700 can be attached to the memory die 900 by bonding the controller-die front bonding structures 798 to the memory-die front bonding structures 198. The bonding between mating pairs of a respective memory die 900 and a respective memory-controller die 700 may be performed employing a wafer-to-wafer bonding process in which a two-dimensional array of memory dies 900 is bonded to a two-dimensional array of memory-controller dies 700, by a die-to-wafer bonding process (in which a diced die is bonded to a wafer), or by a die-to-die bonding process (in which two diced dies are bonded to each other). The controller-die front bonding structures 798 within each memory-controller die 700 can be bonded to the memory-die front bonding structures 198 within a respective memory die 900 by metal-to-metal bonding, such as copper-to-copper bonding.

The memory die 900 comprises alternating stacks (32, 46) of insulating layers 32 and electrically conductive layers 46 and memory-die front dielectric material layers 160 embedding memory-die metal interconnect structures (180, 108, 98) and memory-die front bonding structures 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. In one embodiment, through-stack via structures 486 vertically extend through vertically-extending openings 489 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A memory-controller die 700 comprises a memory controller circuit 720 including a control circuitry for controlling operation of the electrically conductive layers 46 and further comprises controller-die front dielectric material layers 760 embedding controller-die front metal interconnect structures 780 and controller-die front bonding structures 798. The controller-die front bonding structures 798 are bonded to the memory-die front bonding structures 198.

Within each bonded assembly 1000 (i.e., a unit bonded assembly 1000) of a respective memory die 900 and a respective memory-controller die 700, the respective memory die 900 comprises respective memory-die front bonding structures 198 embedded within respective memory-die front dielectric material layers 160, and the respective memory-controller die 700 comprises respective controller-die front bonding structures 798 embedded within respective controller-die front dielectric material layers 760 and bonded to the respective memory-die front bonding structures 198. In one embodiment, the respective controller-die front bonding structures 798 are bonded to the respective memory-die front bonding structures 198 via metal-to-metal bonding, such as copper-to-copper bonding.

In one embodiment, dielectric-to-dielectric bonding, such as silicon oxide-to-silicon oxide bonding may be employed in conjunction with the metal-to-metal bonding. In this case, a topmost memory-die front dielectric material layer of the respective memory-die front dielectric material layers 160 is bonded to a topmost controller-die front dielectric material layer among the controller-die front dielectric material layers 760 via dielectric-to-dielectric bonding (i.e., hybrid bonding is used to bond the respective memory die to the respective memory-controller die).

In one embodiment, the respective memory die 900 includes a respective three-dimensional array of memory elements (e.g., flash memory cells comprising as portions of a memory material layer 54), and the respective memory-controller die 700 includes a respective memory controller circuit 720 configured to control operation of the respective three-dimensional array of memory elements. In one embodiment, a subset of the through-stack via structures 486 is electrically connected to a subset of semiconductor devices (e.g., input/output control devices, such as field effect transistors) in the respective memory controller circuit 720 of the memory-controller die 700 through a subset of the memory-die metal interconnect structures (180, 108, 98) and through a subset of the controller-die front metal interconnect structures 780.

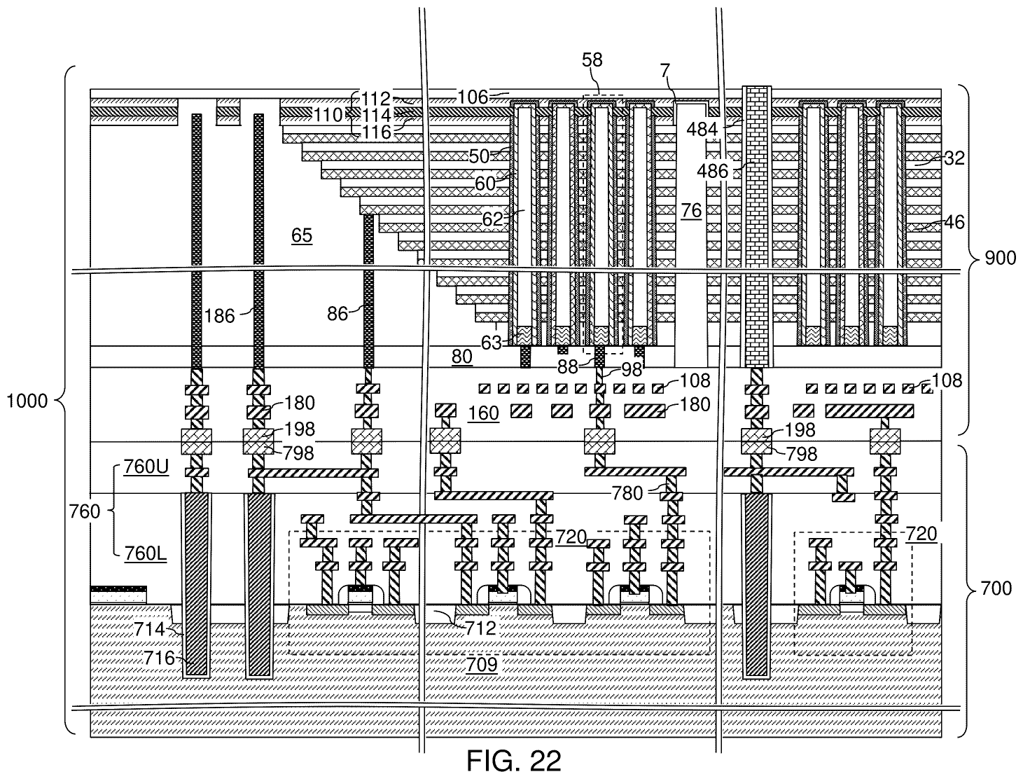

Referring to FIG. 22, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the topmost memory-die backside dielectric layer 106 may be subsequently employed as a polishing stopper material layer. If an etch process such as a wet etch process is employed to remove the carrier substrate 9, the topmost memory-die backside dielectric layer 106 may be subsequently employed as an etch stop material layer. End surfaces of the through-stack via structures 486 may be physically exposed upon removal of the carrier substrate 9.

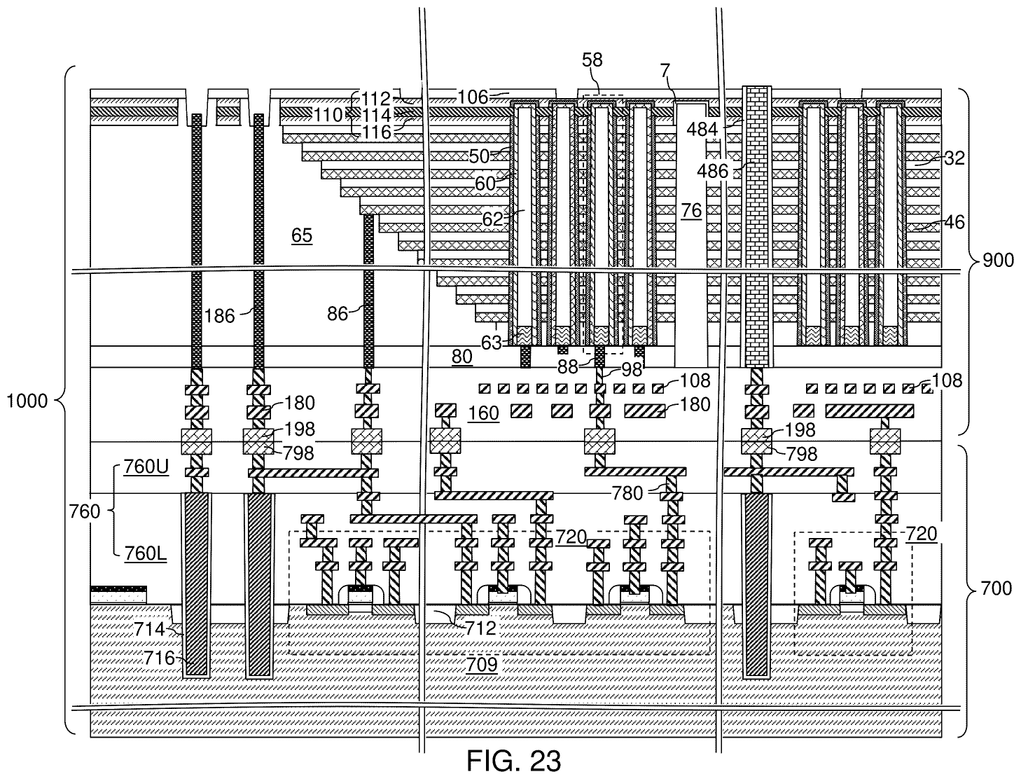

Referring to FIG. 23, backside via openings can be formed through the topmost memory-die backside dielectric layer 106 on the backside surface (i.e., a distal surface) of the source layer 110 by performing a combination of a lithographic patterning process and an anisotropic etch process. Additional backside via openings can be formed through the topmost memory-die backside dielectric layer 106 and through the source layer 110 over the end portions of the peripheral connection via structures 186 by performing a combination of an additional lithographic patterning process and an additional anisotropic etch process.

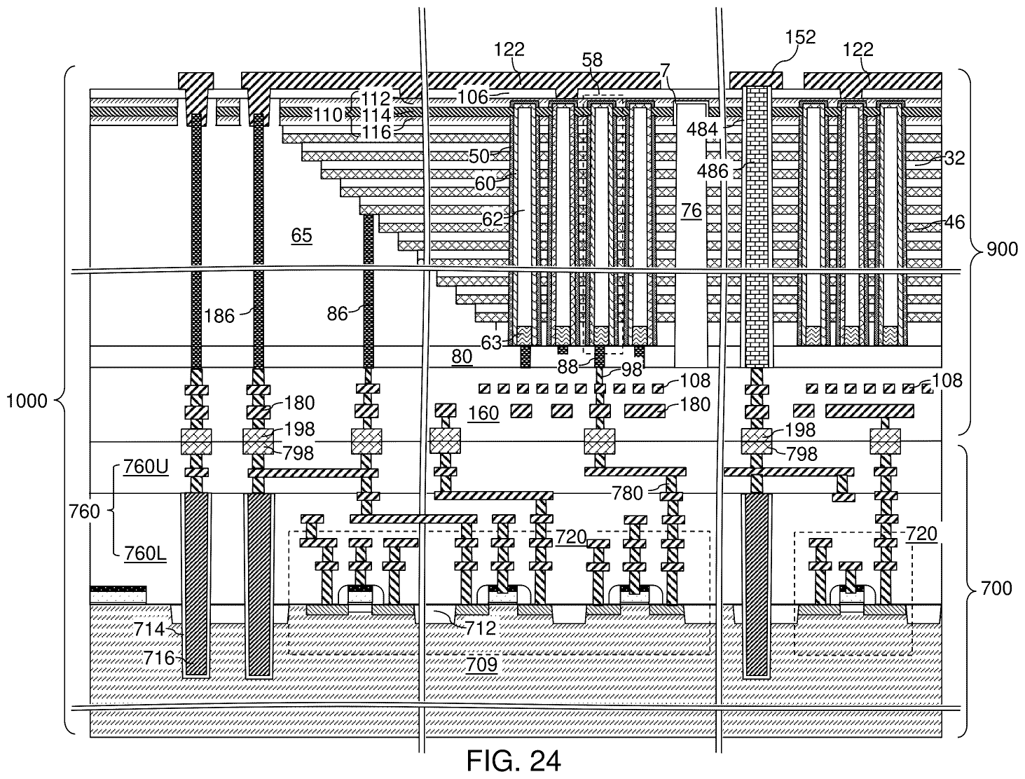

Referring to FIG. 24, at least one electrically conductive material can be deposited in the openings, over the distal surface of the topmost memory-die backside dielectric layer 106, and over end portions of the memory stack structures 55 that are distal from an interface between the memory die 900 and the memory-controller die 700 to form a backside conductive layer. The at least one electrically conductive material may comprise a stack of a metallic diffusion barrier material (such as TiN, TaN, MON, and/or WN) and a high-electrical-conductivity metal (such as Cu, W, Ti, Ta, Co, Ru, etc). The backside conductive layer can be subsequently patterned to form at least one source connection structure 122 and memory-die backside metal interconnect structures 152. Each of the at least one source connection structure 122 may be electrically connected to a respective source line driver through a respective peripheral connection via structure 186, a respective subset of the memory-dic metal interconnect structures 180, a respected bonded pair of a controller-die front bonding structure 798 and a memory-die front bonding structure 198, and a respective subset of the controller-die front metal interconnect structures 780. Each source connection structure 122 is electrically connected to the end portions of a respective subset of the memory stack structures 55 (e.g., to source side end portions of the vertical semiconductor channels 60). Each of the through-stack via structures 486 may be physically and/or electrically connected to a respective one of the memory-die backside metal interconnect structures 152. At least a subset of the memory-die backside metal interconnect structures 152 can be electrically connected to a respective input/output control circuit within the memory controller circuit 720 through a respective through-stack via structure 486, a respective subset of the memory-die metal interconnect structures 180, a respected bonded pair of a controller-die front bonding structure 798 and a memory-die front bonding structure 198, and a respective subset of the controller-die front metal interconnect structures 780.

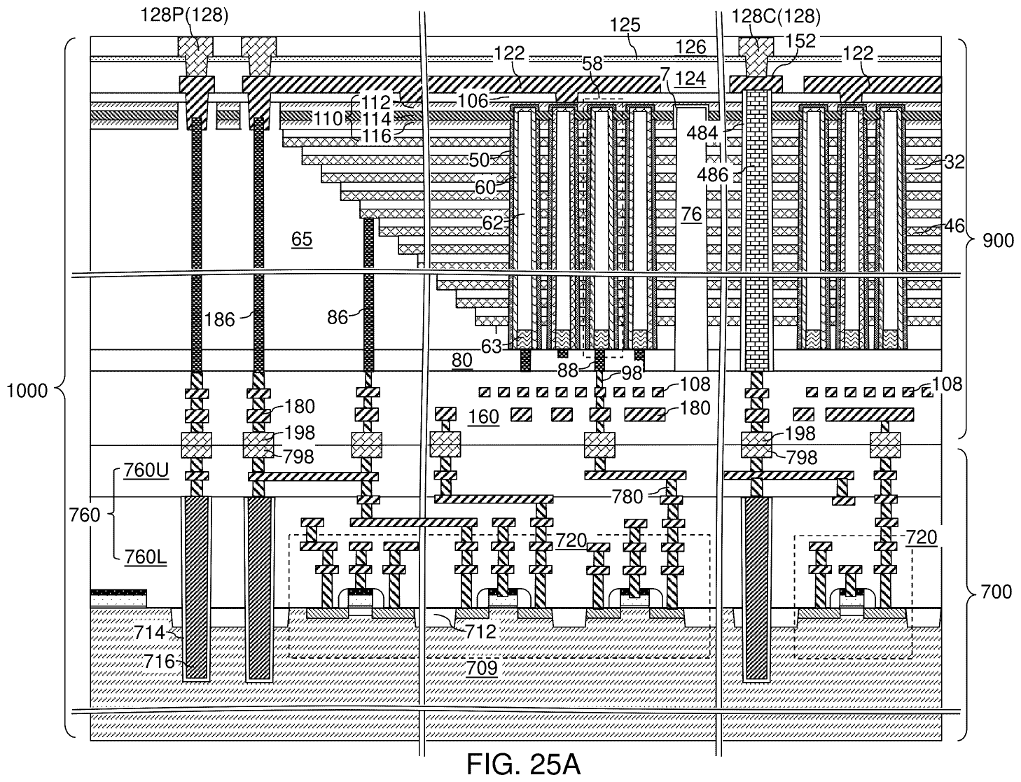

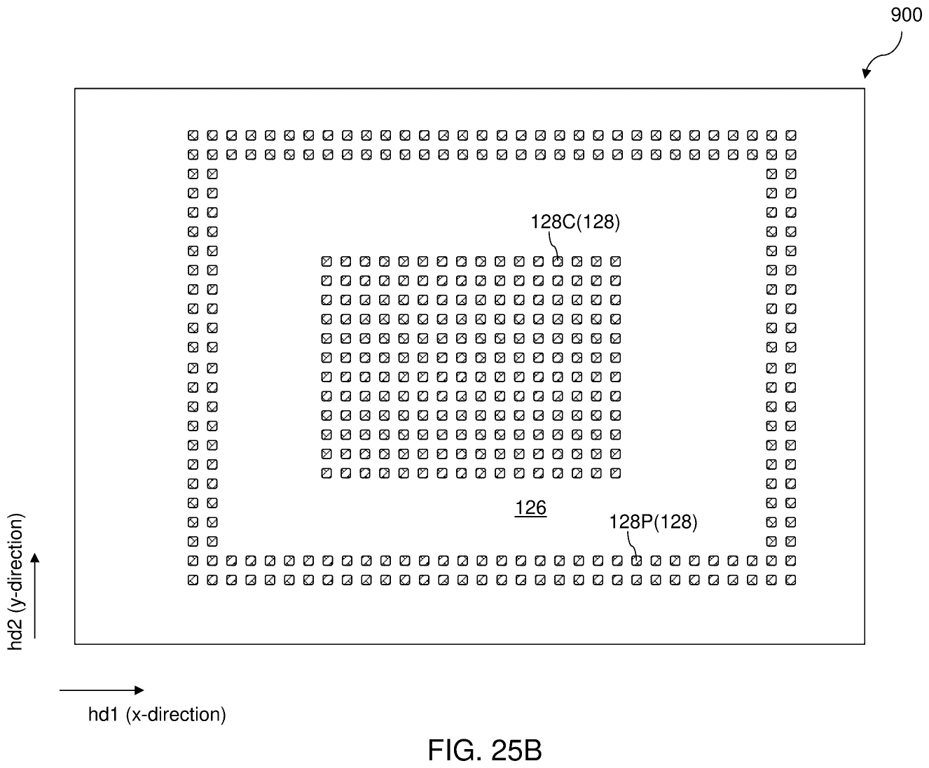

Referring to FIGS. 25A and 25B, additional memory-die backside dielectric layers (124, 125, 126) can be formed over the at least one source connection structure 122 and the memory-die backside metal interconnect structures 152. The additional memory-die backside dielectric layers (124, 125, 126) may comprise, for example, a stack of a stack of a silicon oxide passivation layer 124, a silicon nitride passivation layer 125, and a distal memory-side backside dielectric (e.g., silicon oxide) layer 126. Generally, any combination of interlayer dielectric (ILD) material layers may be employed for the additional memory-die backside dielectric layers (124, 125, 126) provided that the distal memory-side backside dielectric layer 126 comprises a suitable dielectric material (such as silicon oxide or silicon nitride) for embedding metallic bonding structures. Optionally, additional memory-die and/or memory-controller die backside metal interconnect structures can be formed in the additional memory-die backside dielectric layers (124, 125, 126). For example, memory-controller backside metal line structures (not shown) and memory-controller backside metal via structures (not shown) may be formed in the additional memory-die backside dielectric layers (124, 125, 126).

A photoresist layer can be applied over the additional memory-die backside dielectric layers (124, 125, 126), and can be lithographically patterned to form openings over the memory-die backside metal interconnect structures 152. An anisotropic etch process can be performed to form openings through the additional memory-die backside dielectric layers (124, 125, 126) over each of the memory-die backside metal interconnect structures 152. The openings may have pad patterns only, or may have a combination of via patterns and pad patterns.

At least one metallic material suitable for forming bonding structures can be deposited into the openings in the additional memory-die backside dielectric layers (124, 125, 126), and may be patterned to form memory-die backside bonding structures 128. The memory-die backside bonding structures 128 may comprise central memory-die backside bonding structures 128C that are electrically connected to a respective one of the through-stack via structures 486 through the memory-die backside metal interconnect structures 152, and peripheral memory-die backside bonding structures 128P that are electrically connected to a respective one of the peripheral connection via structures 186

In one embodiment, the memory-die backside bonding structures 128 may comprise bonding structures that are employed to bond solder balls. The memory-die backside bonding structures 128 may be configured for microbump bonding (which is also known as chip connection bonding or C2 bonding). The top surfaces of the memory-die backside bonding structures 128 may be coplanar with a distal horizontal surface of the distal memory-side backside dielectric layer 126, or may protrude vertically outward from the distal horizontal surface of the distal memory-side backside dielectric layer 126. The lateral dimensions (such as a diameter) of each memory-die backside bonding structure 128 may be in a range from 10 microns to 60 microns, such as from 15 microns to 40 microns, although lesser and greater dimensions may also be employed.

In one embodiment, each of the memory-die backside bonding structures 128 may comprise a conductive layer stack that is compatible with a solder bonding process. For example, each of the memory-die backside bonding structures 128 may comprise, from bottom to top, a metallic barrier liner comprising a conductive metallic nitride material (such as TiN, TaN, WN, or MoN), a high-electrical-conductively metal layer comprising copper or aluminum, a metallic diffusion barrier liner comprising a diffusion barrier metallic material, such as Ti, TiW, Ta, or TaN, an adhesion layer enhancing the adhesion strength of subsequently deposited layers and comprising a material such as Cr, Ti, or a Cr/Ti alloy, and an under-bump metallization (UBM) layer. The UBM layer may comprise a multi-layer stack, such as a layer stack of a copper layer, a nickel layer, and a gold layer. Alternative UBM layer compositions may also be employed.

A plurality of unit bonded assemblies 1000 may be provided. Each of the unit bonded assemblies 1000 contains a respective memory die 900 including a respective three-dimensional array of memory elements (comprising portions of a memory material layer 54) and a respective memory-controller die 700 including a respective memory controller circuit 720 configured to control operation of the respective three-dimensional array of memory elements. In one embodiment, each memory die 900 within the plurality of bonded assemblies 1000 comprises a source connection structure 122 electrically connected to the vertical semiconductor channels 60 and embedded within the memory-die backside dielectric layers (106, 124, 125, 126). A subset of the memory-die backside metal interconnect structures 152 is located within openings in the respective source connection structure 122 and provides electrical connection between a subset 128C of the memory-die backside bonding structures 128 and a subset of the through-stack via structures 486. In one embodiment, each memory die 900 within the plurality of bonded assemblies 1000 comprises a respective memory-die backside dielectric layer (such as a distal memory-die backside dielectric layer 126) embedding respective memory-die backside bonding structures 128.

In some embodiments, the distal memory-die backside dielectric layer 126 may comprise a dielectric material that may be subsequently recessed (for example, after thinning of the semiconductor substrate 709 of the memory-controller die 700) or removed so that the memory-die backside bonding structures 128 protrude outward from the recessed horizontal surface of the distal memory-die backside dielectric layer 126, or from a physically exposed surface of another distal memory-die backside dielectric layer (such as the silicon nitride passivation layer 125). While an embodiment is described in which a pad portion or a pillar portion of the memory-die backside bonding structures 128 have bonding surfaces located within the horizontal plane including the distal horizontal surface of the memory-die backside dielectric layer (106, 124, 125, 126), other embodiments are expressly contemplated in which the memory-die backside bonding structures 128 protrude outward vertically from the horizontal plane including the distal horizontal surface of the memory-die backside dielectric layers (106, 124, 125, 126).

Within each memory die 900, memory-die backside dielectric layers (106, 124, 125, 126) may embed memory-die backside metal interconnect structures 152, and memory-die backside bonding structures 128 may be in contact with a distal memory-die backside dielectric layer 126 of the memory-die backside dielectric layers (106, 124, 125, 126).

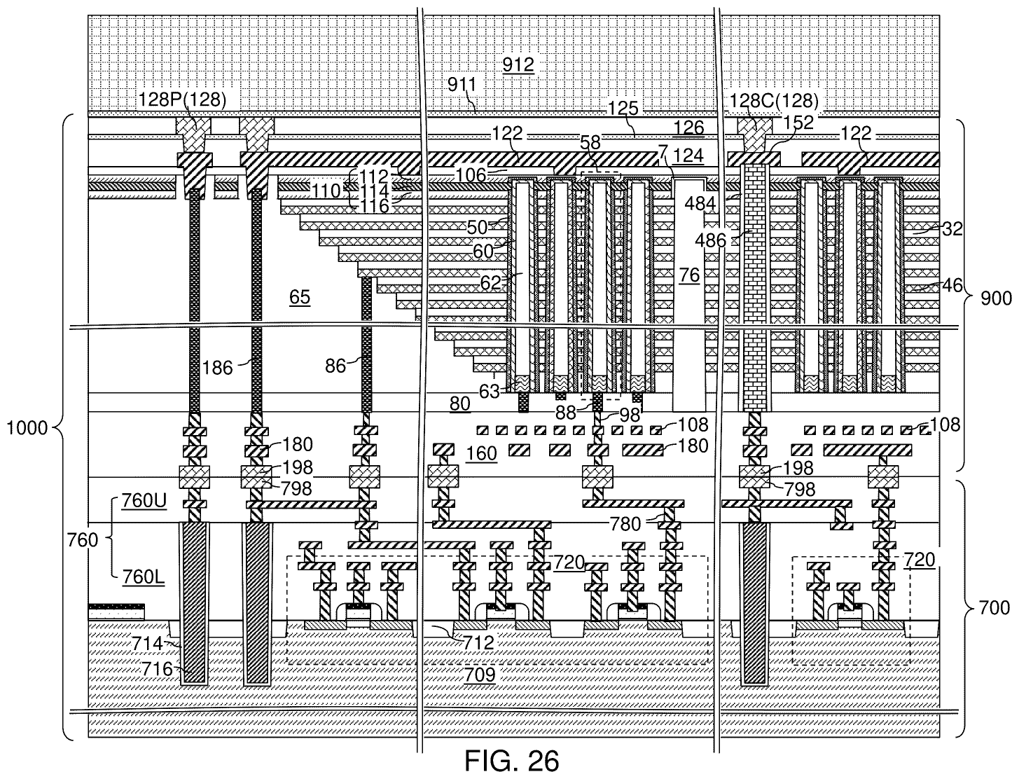

Referring to FIG. 26, a carrier substrate 912 can be attached to the bonded assembly 1000 through an adhesive layer 911. The adhesive layer 911 may comprise a thermally decomposable adhesive material such as polyimide, or may comprise an ultraviolet decomposable adhesive material such as acrylic-based ultraviolet (UV) tape. The carrier substrate 912 may comprise a semiconductor material such as silicon, a dielectric material such as glass or plastic, or a conductive material. The thickness of the carrier substrate 912 may be selected such that carrier substrate 912 can provide structural support to the unit bonded assembly 1000 during subsequent thinning of the semiconductor substrate 709 of the memory-controller die 700.

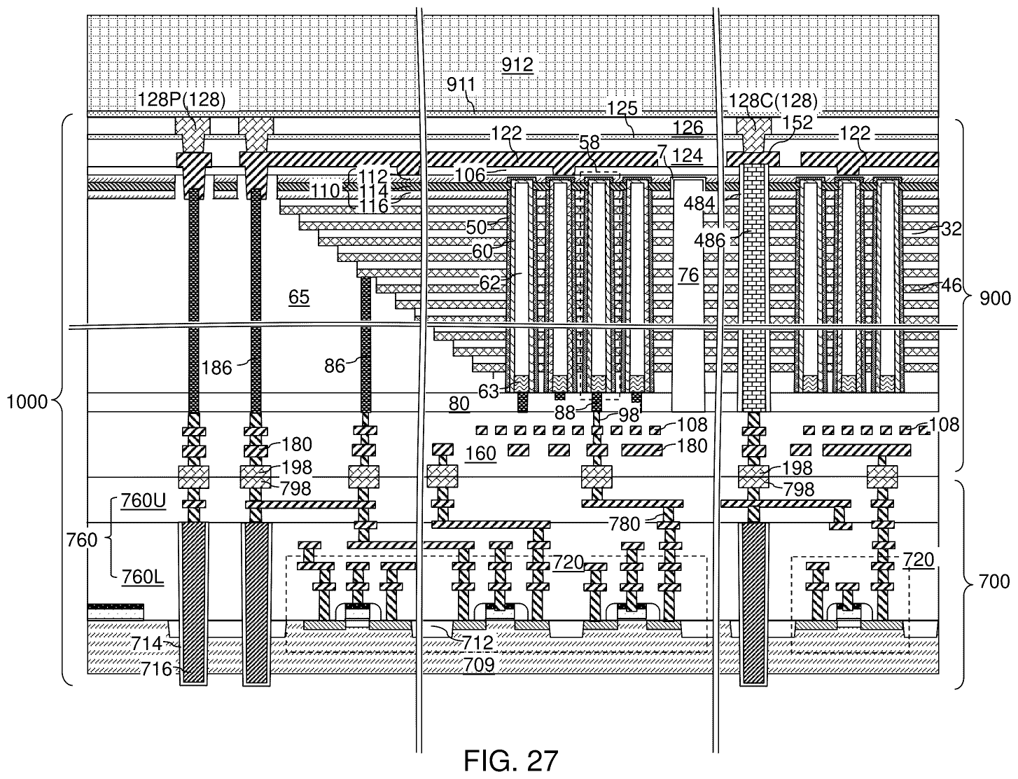

Referring to FIG. 27, the backside of the semiconductor substrate 709 of the memory-controller die 700 can be removed by grinding, polishing, an isotropic etch process (such as a wet etch process), an anisotropic etch process (such as a reactive ion etch process), or a combination thereof. The removal of the backside of the semiconductor substrate 709 may be selective to the material of the TSV structures 716 or to the material of the dielectric spacers 714. Bottom surfaces of the TSV structures 716 may protrude outward (i.e., downward) from the horizontal plane including the recessed bottom surface of the semiconductor substrate 709 of the memory-controller die 700.

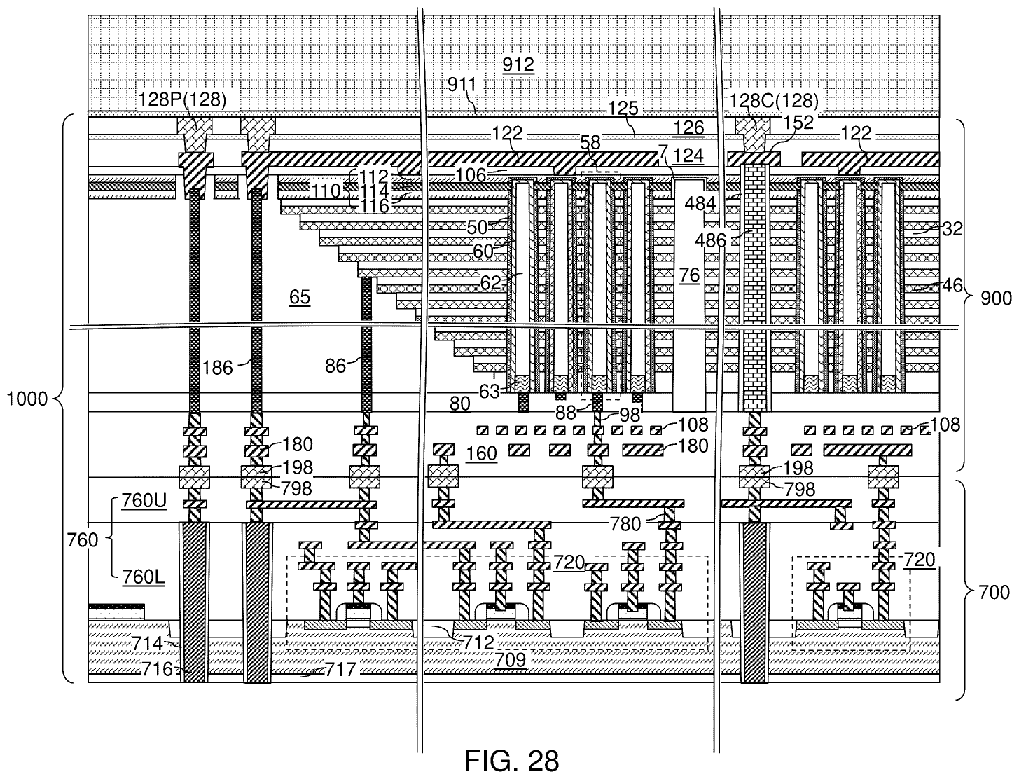

Referring to FIG. 28, an optional controller-die backside dielectric layer 717 can be deposited on the backside surface of the semiconductor substrate 709 of the memory-controller die 700 and then planarized to expose the TSV structures 716. Optionally, protruding portions of the TSV structures 716 may be planarized so that bottom surfaces of the TSV structures 716 are coplanar with the physically exposed bottom surface of the controller-die backside dielectric layer 717. The thickness of the controller-die backside dielectric layer 717 may be in a range from 100 nm to 3,000 nm, such as from 300 nm to 1,000 nm, although lesser and greater thicknesses may also be employed.

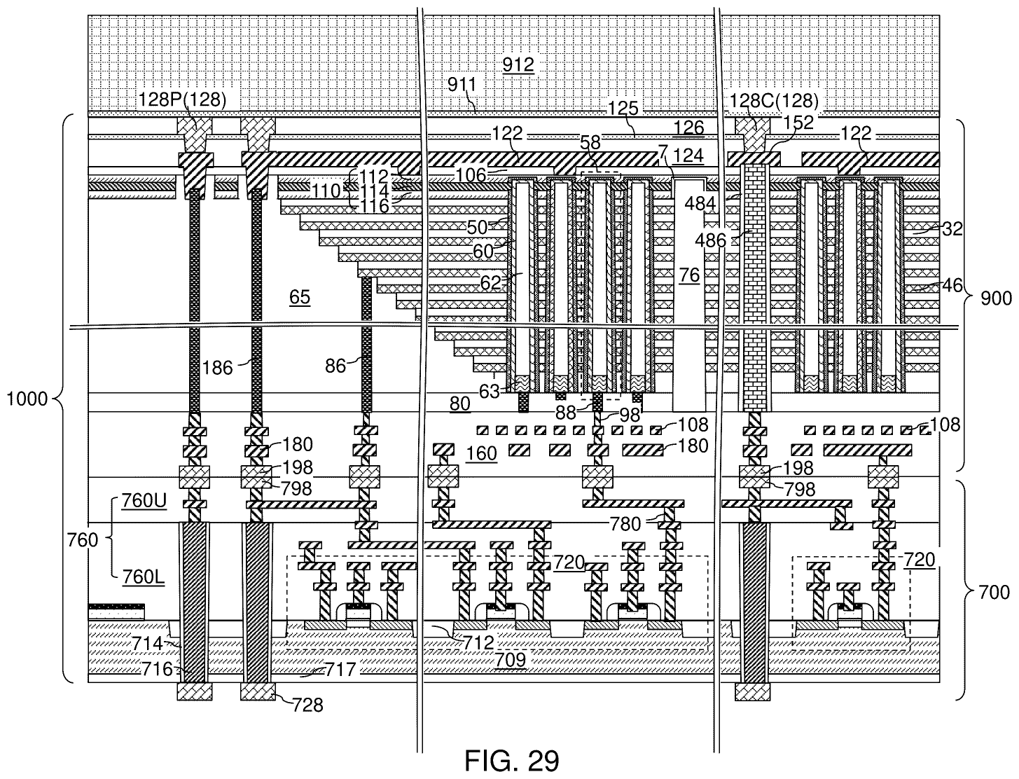

Referring to FIG. 29, controller-die backside bonding structures 728 can be formed on the physically exposed end surfaces of the TSV structures 716. In one embodiment, the controller-die backside bonding structures 728 may comprise solder bonding structures that are employed to bond solder balls. The controller-die backside bonding structures 728 may be configured for microbump bonding (which is also known as chip connection bonding or C2 bonding). In one embodiment, each of the controller-die backside bonding structures 728 may comprise a conductive layer stack that is compatible with a solder bonding process. For example, each of the controller-die backside bonding structures 728 may comprise, from bottom to top, a metallic barrier liner comprising a conductive metallic nitride material (such as TiN, TaN, WN, or MoN), a high-electrical-conductively metal layer comprising copper or aluminum, a metallic diffusion barrier liner comprising a diffusion barrier metallic material, such as Ti, TiW, Ta, or TaN, an adhesion layer enhancing the adhesion strength of subsequently deposited layers and comprising a material such as Cr, Ti, or a Cr/Ti alloy, and an under-bump metallization (UBM) layer. The UBM layer may comprise a multi-layer stack, such as a layer stack of a copper layer, a nickel layer, and a gold layer. Alternative UBM layer compositions may also be employed.

Each controller-die backside bonding structure 728 can be in contact with at least a portion of the controller-die backside dielectric layer 717. For example, a horizontal proximal surface of each controller-die backside bonding structure 728 may be in contact with the controller-die backside dielectric layer 717.

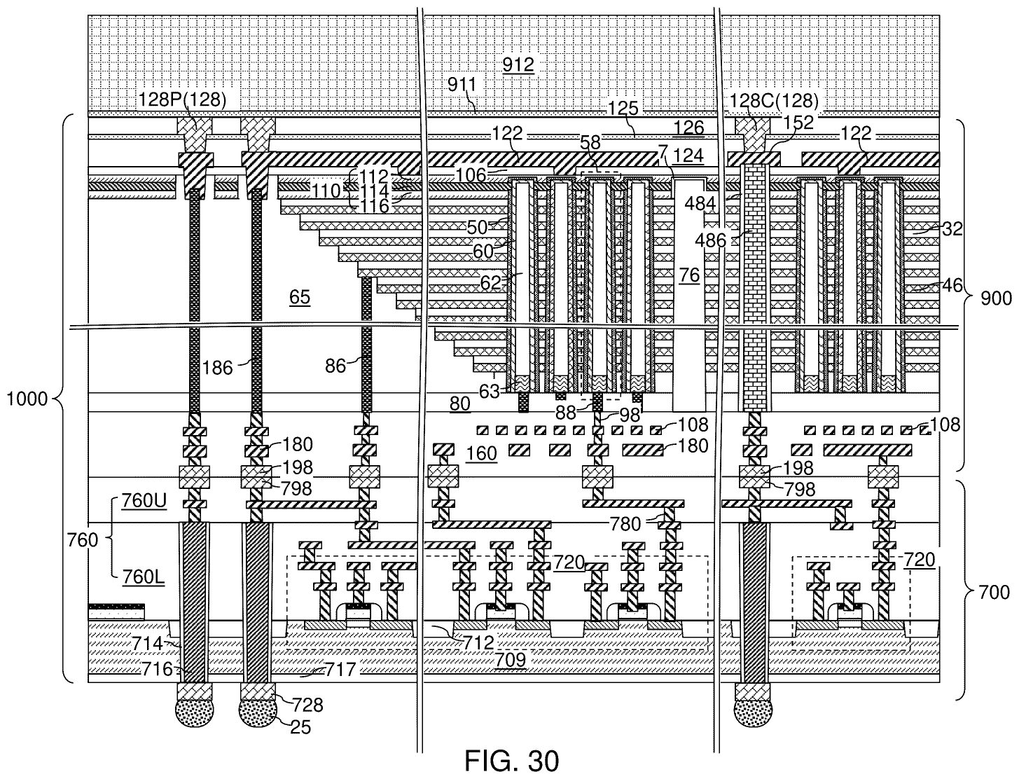

Referring to FIG. 30, solder material portions 25 may be attached to each of the controller-die backside bonding structure 728.

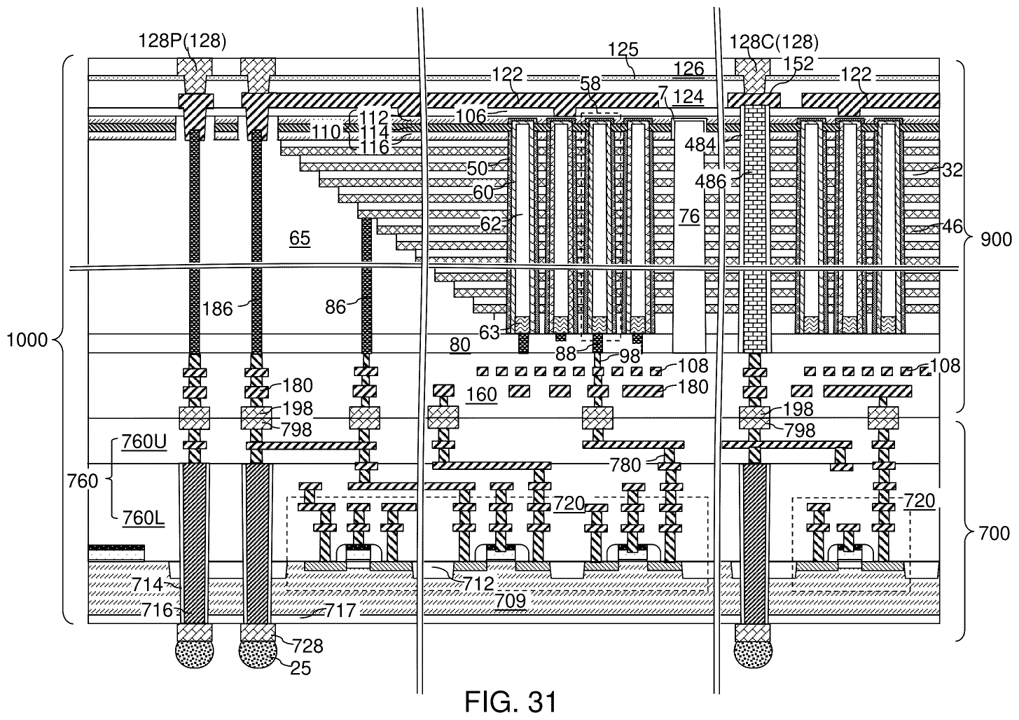

Referring to FIG. 31, the carrier substrate 912 can be detached from the unit bonded assembly 1000 by decomposing the adhesive layer 911. The decomposition of the adhesive layer 911 may be effected by a thermal anneal or by ultraviolet irradiation. A suitable surface clean process may be performed to remove residual materials from the physically exposed surfaces of the memory-die backside dielectric layers (106, 124, 125, 126) and the memory-die backside bonding structures 128.

A plurality of unit bonded assemblies 1000 may be provided. In one embodiment, the memory-controller die 700 in each unit bonded assembly 1000 may comprise respective controller-die front bonding structures 798 embedded within respective controller-die front dielectric material layers 760 and bonded to the respective memory-die front bonding structures 198. The respective controller-die front bonding structures 798 are bonded to the respective memory-die front bonding structures 198 via metal-to-metal bonding. In one embodiment, a topmost memory-die front dielectric material layer among the respective memory-die front dielectric material layers 160 is bonded to a topmost controller-die front dielectric material layer among the controller-die front dielectric material layers 760 via dielectric-to-dielectric bonding.

In an alternative embodiment, the solder material portions 25 may be attached to each of the controller-die backside bonding structure 728 after detaching the carrier substrate 912.

The bonded assemblies 1000 may be separated from each other by dicing or other die or chip separation. Thus, each bonded assembly 1000 may comprise a free standing chip. The separation (e.g., dicing) may be performed before or after detaching the carrier substrate 912, and before or after the solder material portions 25 are attached to each of the controller-die backside bonding structure 728.

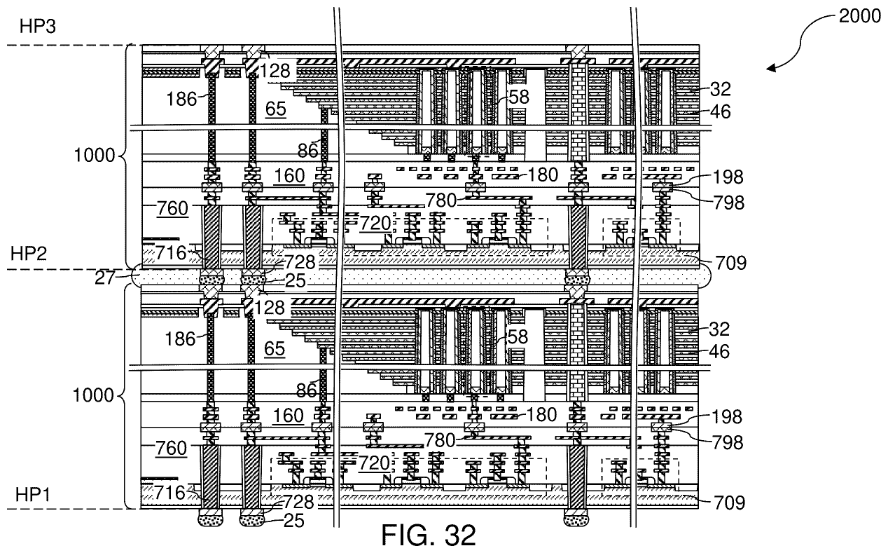

FIGS. 32, 33, 34, and 35 illustrate various embodiments of a stack of separated (i.e., diced) bonded assemblies 1000 that can be formed by stacking (e.g., vertically stacking) and bonding plural bonded assemblies 1000 illustrated in FIG. 31 to each other. The stacking and bonding may comprise any suitable chip level stacking and bonding method, such as a solder bonding method.

FIG. 32 is a vertical cross-sectional view of a first exemplary vertical stack of two bonded assemblies 1000 configured for bonding to semiconductor package structure, such as a system level logic die, an interposer and/or a package substrate, through an array of solder material portions 25 formed on one of the memory-controller dies 700.

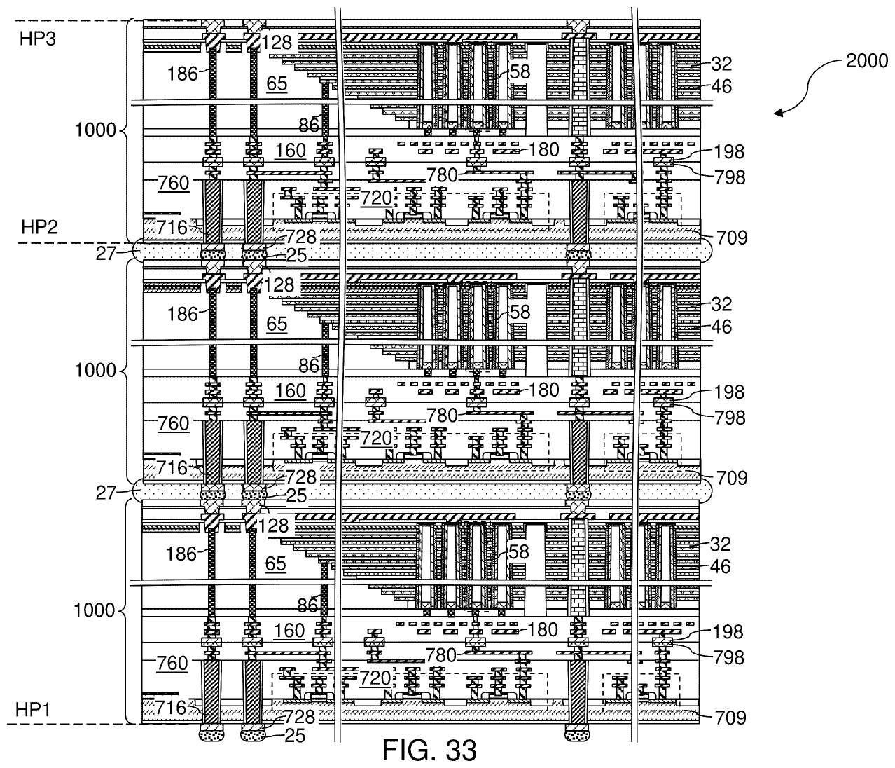

FIG. 33 is a vertical cross-sectional view of a second exemplary vertical stack of three bonded assemblies 1000 configured for bonding with a semiconductor package structure, through an array of solder material portions 25 formed on one of the memory-controller dies 700.

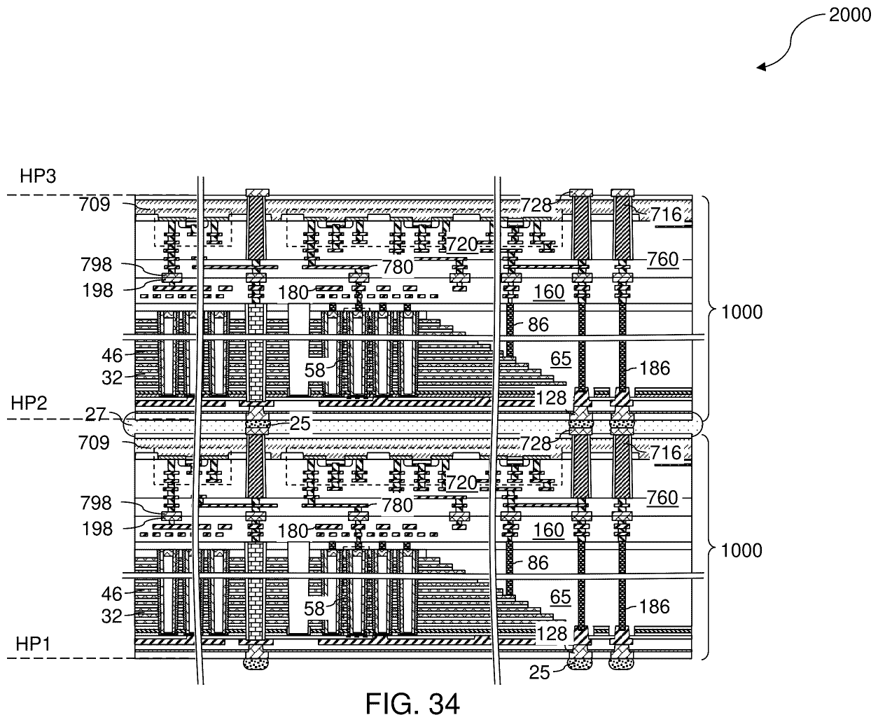

FIG. 34 is a vertical cross-sectional view of an alternative configuration of the first exemplary vertical stack of two bonded assemblies 1000 configured for bonding with a semiconductor package structure, through an array of solder material portions 25 formed on one of the memory dies 900. In this alternative configuration, the solder material portions 25 are formed on the memory dies 900 instead of on the memory-controller dies 700. The memory dies 900 may be located below the memory controller dies 700 in this configuration.

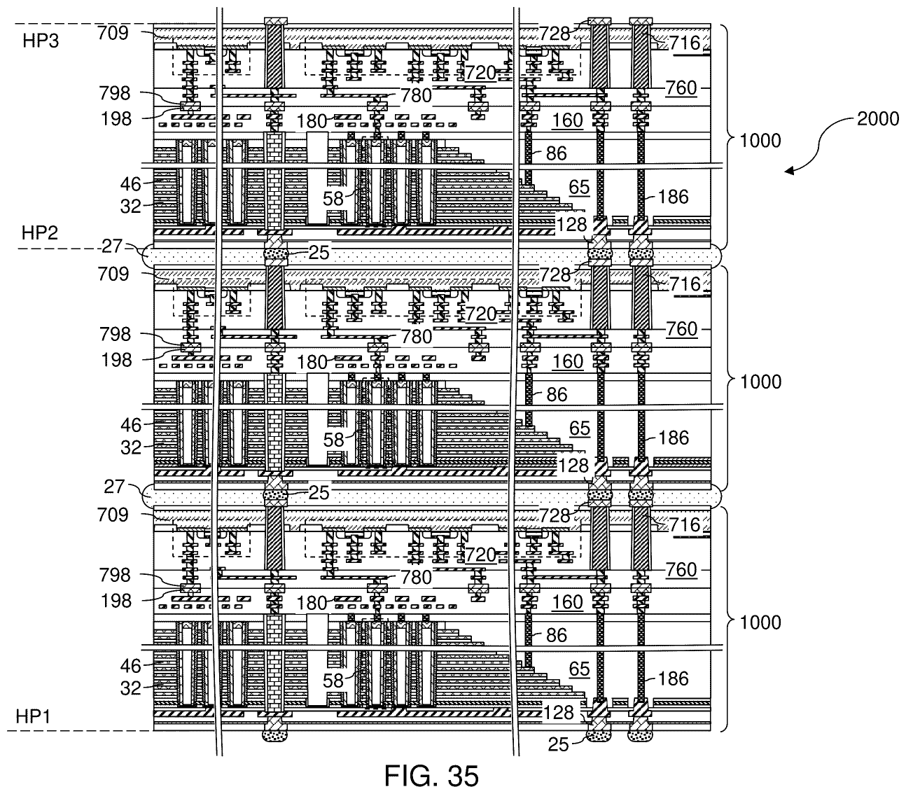

FIG. 35 is a vertical cross-sectional view of an alternative configuration of the second exemplary vertical stack of three bonded assemblies 1000 configured for bonding with a semiconductor package structure, such as a logic die or an interposer, through an array of solder material portions 25 formed on one of the memory dies 900. In this alternative configuration, the solder material portions 25 are formed on the memory dies 900 instead of on the memory-controller dies 700. The memory dies 900 may be located below the memory controller dies 700 in this configuration.

Each vertical stack of two or more bonded assemblies 1000 constitutes a high bandwidth flash memory stack 2000. In the exemplary vertical stacks illustrated in FIGS. 32-35, each vertically neighboring pair of unit bonded assemblies 1000 can be bonded to each other through a respective array of solder material portions (e.g., solder micro bumps or balls) 25. The solder material portions 25 are bonded to an array of memory-die backside bonding structures (e.g., memory redistribution layers, RDLs and/or UMBs) 128 and bonded to an array of controller-die backside bonding structures (e.g., controller redistribution layers, RDLs and/or UBMs) 728. An insulating underfill material (e.g., polymer) portion 27 can be applied to the gap between each vertically neighboring pair of unit bonded assemblies 1000 around a respective array of solder material portions 25.

In one embodiment, each vertically neighboring pair of the bonded assemblies 1000 is bonded to each other through a respective pair of arrays of bonding structures (198, 798) such that electrically conductive paths vertically extend from a first horizontal plane HP1 including a bottom surface of a bottommost bonded assembly 1000 of the plurality of bonded assemblies 1000 at least to a second horizontal plane HP2 including a bottom surface of a topmost bonded assembly 1000 of the plurality of bonded assemblies 1000. In one embodiment, the electrically conductive paths vertically extend to a third horizontal plane HP3 including a top surface of the topmost bonded assembly 1000 of the plurality of bonded assemblies 1000.

In one embodiment, a memory die 900 is present between each vertically neighboring pair of memory-controller dies 700 within the plurality of bonded assemblies 1000; and a memory-controller die 700 is present between each vertically neighboring pair of memory dies 900 within the plurality of bonded assemblies 1000.

In one embodiment, for each vertically neighboring pair of unit bonded assemblies 1000, memory-die backside bonding structures 128 of a memory die 900 of a first unit bonded assembly 1000 within said each vertically neighboring pair of unit bonded assemblies 1000 are bonded to controller-die backside bonding structures 728 of a memory-controller die 700 of a second unit bonded assembly 1000 within said each vertically neighboring pair of unit bonded assemblies 1000 through a respective array of solder material portions 25. In one embodiment, a memory-die backside dielectric layer (such as a distal memory-die backside dielectric layer 126) of the memory die 900 of the first unit bonded assembly 1000 within said each vertically neighboring pair of unit bonded assemblies 1000 has a distal surface located within a horizontal plane including bonding surfaces of the memory-die backside bonding structures 128 of the memory die 900 of the first unit bonded assembly 1000.

The high bandwidth flash memory stack 2000 of the embodiments of the present disclosure can be bonded to a system level logic die or an interposer. The high bandwidth flash memory stack 2000 of the present disclosure may include multiple memory dies 900 including a respective three-dimensional memory array such as a respective three-dimensional NAND or NOR flash memory.

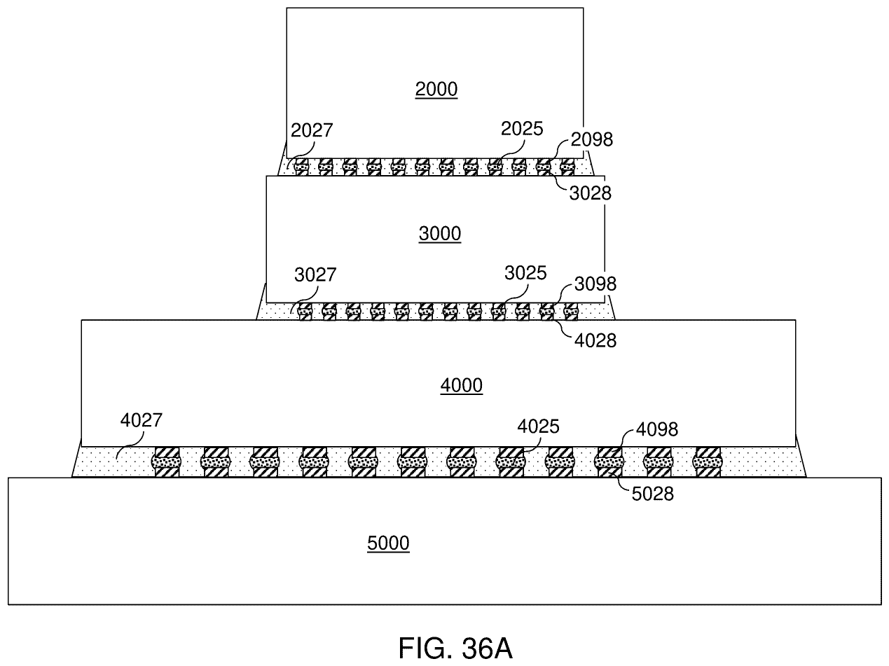

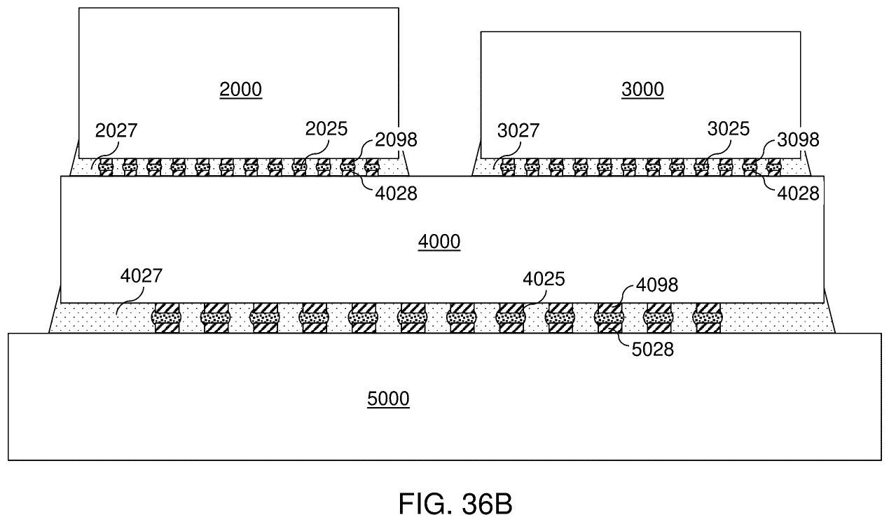

FIGS. 36A and 36B illustrate exemplary configurations that may be employed to bond the high bandwidth flash memory stack 2000 of the embodiments of the present disclosure to a semiconductor package structure. FIG. 36A is a vertical cross-sectional view of a first exemplary bonded assembly including a high bandwidth flash memory stack 2000, an optional system level logic die 3000, an optional interposer 4000, and a packaging substrate 5000 according to an embodiment of the present disclosure. The packaging level substrate 500 may comprise a printed circuit board or another supporting substrate containing electrical leads of a semiconductor chip package. FIG. 36B is a vertical cross-sectional view of a second exemplary bonded assembly including the high bandwidth flash memory stack 2000, the optional system level logic die 3000, the optional interposer 4000, and the packaging substrate 5000 according to an embodiment of the present disclosure.

The system level logic die 3000, if present, controls the operation of the memory-controller dies 700 in each bonded assembly 1000 of the high bandwidth flash memory stack 2000. The system level logic die 3000 may be bonded to the high bandwidth flash memory stack 2000 either through an array of solder material portions (e.g., solder micro bumps or balls) 3025 as illustrated in FIG. 36A, or through a combination of the interposer 4000 and two arrays of solder material portions (2025, 3025) as illustrated in FIG. 36B.

In the example illustrated in FIG. 36A, the high bandwidth flash memory stack 2000 may comprise memory-side bonding structures 2098, which may be the controller-die backside bonding structures 728 of the bottommost memory-controller die 700 (as illustrated in FIGS. 32 and 33), or may be the memory-die backside bonding structures 128 of the bottommost memory die 900 (as illustrated in FIGS. 34 and 35). The system level logic die 3000 may comprise logic-die top bonding structures 3028 that are configured to mate with the memory-side bonding structures 2098 through the array of solder material portions 2025. An underfill material portion 2027 may be applied around the array of solder material portions 2025.

The system level logic die 3000 may also comprise logic-die bottom bonding structures 3098, and the interposer 4000 may comprise interposer top bonding structures 4028 that are configured to mate with the logic-die bottom bonding structures 3098 through the array of solder material portions 3025. An underfill material portion 3027 may be applied around the array of solder material portions 3025.

The interposer 4000 may also comprise interposer bottom bonding structures 4098, and the packaging substrate 5000 may comprise packaging-substrate bonding structures 5028 that are configured to mate with the interposer bottom bonding structures 4098 through an array of solder material portions 4025. An underfill material portion 4027 may be applied around the array of solder material portions 4025. The interposer 4000 includes conductive lines or traces (not shown) which extend through the body of the interposer and electrically connect the interposer top bonding structures 4028 to the interposer bottom bonding structures 4098

In the example illustrated in FIG. 36B, the high bandwidth flash memory stack 2000 of the present disclosure and the system logic die 3000 may be bonded to an interposer 4000. In this case, the memory-side bonding structures 2098 of the high bandwidth flash memory stack 2000 may be bonded to a first subset of the interposer top bonding structures 4028, and the logic-die bottom bonding structures 3098 may be bonded to a second subset of the interposer top bonding structures 4028.

A chip connection bonding (C2 bonding) (i.e., microbump bonding) or controlled collapse chip connection bonding (C4 bonding) may be employed for any solder-mediated connection between neighboring pairs of structures in FIGS. 36A and 36B, i.e., the high bandwidth flash memory stack 2000, the system level logic die 3000, the interposer 4000, and/or the packaging substrate 5000.

In summary, each unit bonded assembly 1000 of the plurality of bonded assemblies 1000 contains a respective memory die 900 including a respective three-dimensional array of memory elements (comprising portions of a memory material layer 54) and a respective memory-controller die 700 including a respective memory controller circuit 720 configured to control operation of the respective three-dimensional array of memory elements. A stack of the plurality of bonded assemblies 1000 can be formed to provide a high bandwidth flash memory stack 2000 by bonding the plurality of bonded assemblies 1000 to each other. Each vertically neighboring pair of bonded assemblies 1000 within the vertical stack of the plurality of bonded assemblies 1000 is bonded to each other through a respective pair of arrays of bonding structures (198, 798) such that electrically conductive paths vertically extend from a first horizontal plane HP1 including a bottom surface of a bottommost bonded assembly 1000 within the vertical stack of the plurality of bonded assemblies 1000 at least to a second horizontal plane HP2 including a bottom surface of a topmost bonded assembly 1000 within the vertical stack of the plurality of bonded assemblies 1000.

In one embodiment, the bonded assemblies 1000 within the stack of the plurality of bonded assemblies 1000 are oriented during bonding such that a memory die 900 is present between each vertically neighboring pair of memory-controller dies 700 within the plurality of bonded assemblies 1000; and a memory-controller die 700 is present between each vertically neighboring pair of memory dies 900 within the plurality of bonded assemblies 1000. A bonded system may include the system level logic die 3000 and the vertical stack of the plurality of bonded assemblies 1000. The system level logic die 3000 is bonded to the vertical stack of the plurality of bonded assemblies 1000 through an array of solder material portions 3025 or through a combination of an interposer 4000 and two arrays of solder material portions (2025, 3025).

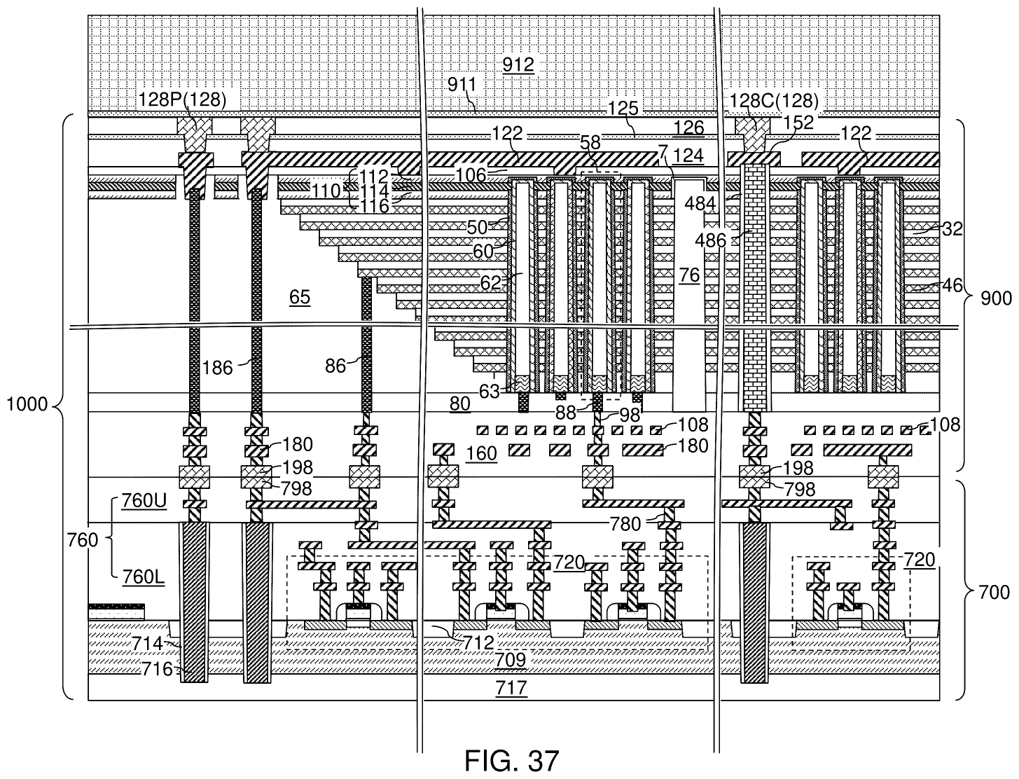

Referring to FIG. 37, an alternative configuration of the exemplary bonded assembly 1000 is illustrated, which can be derived from the exemplary bonded assembly illustrated in FIG. 28 by increasing the thickness of the controller-die backside dielectric layer 717 so that a physically exposed distal surface of the controller-die backside dielectric layer 717 is vertically spaced from and is located below the horizontal plane including the bottom surfaces of the TSV structures 716. In one embodiment, the vertical spacing between the physically exposed distal surface of the controller-die backside dielectric layer 717 and the horizontal plane including the bottom surfaces of the TSV structures 716 may be in a range from 1 micron to 10 microns. In addition, the memory-die backside bonding structures 128 may be configured for metal-to-metal bonding in the alternative configuration of the exemplary bonded assembly. For example, the memory-die backside bonding structures 128 may comprise copper or copper alloy pads that are configured for copper-to-copper bonding. Optionally, the distal memory-die backside dielectric layer 126 may comprise a dielectric material that is conducive to dielectric-to-dielectric bonding (such as silicon oxide).

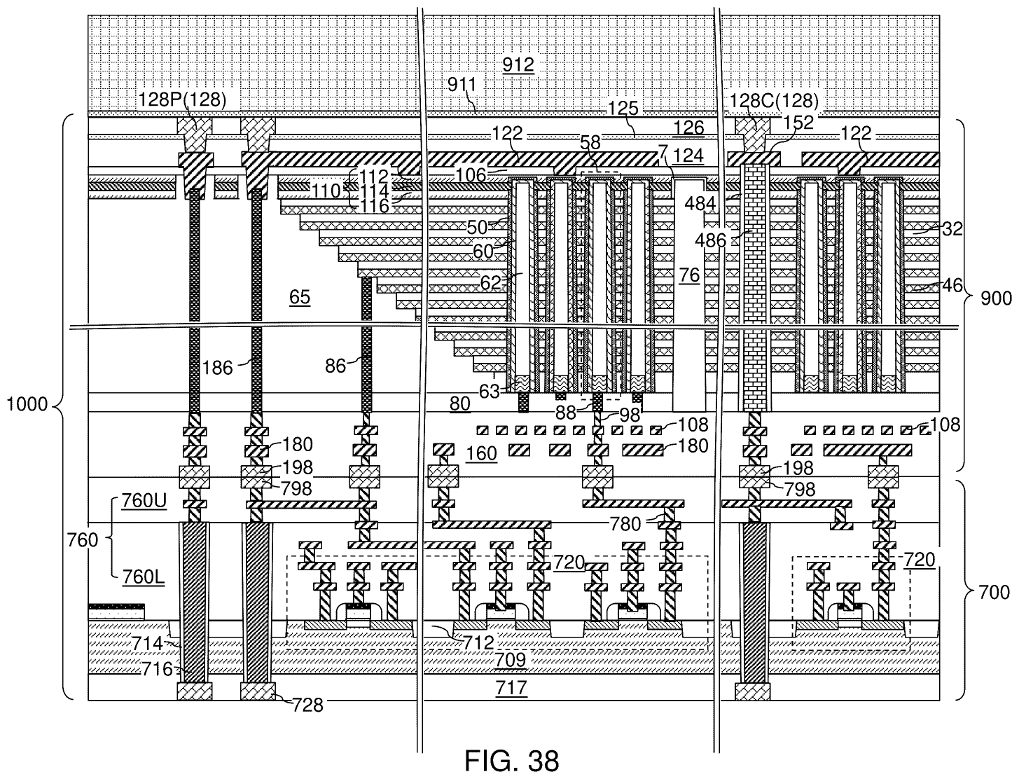

Referring to FIG. 38, pad cavities can be formed in the controller-die backside dielectric layer 717, and can be filled with a conductive material that is conducive to metal-to-metal bonding (such as copper) to form controller-die backside bonding structures 728. The controller-die backside bonding structures 728 may be configured for metal-to-metal bonding. In one embodiment, the controller-die backside bonding structures 728 may comprise copper or copper alloy bonding pads.

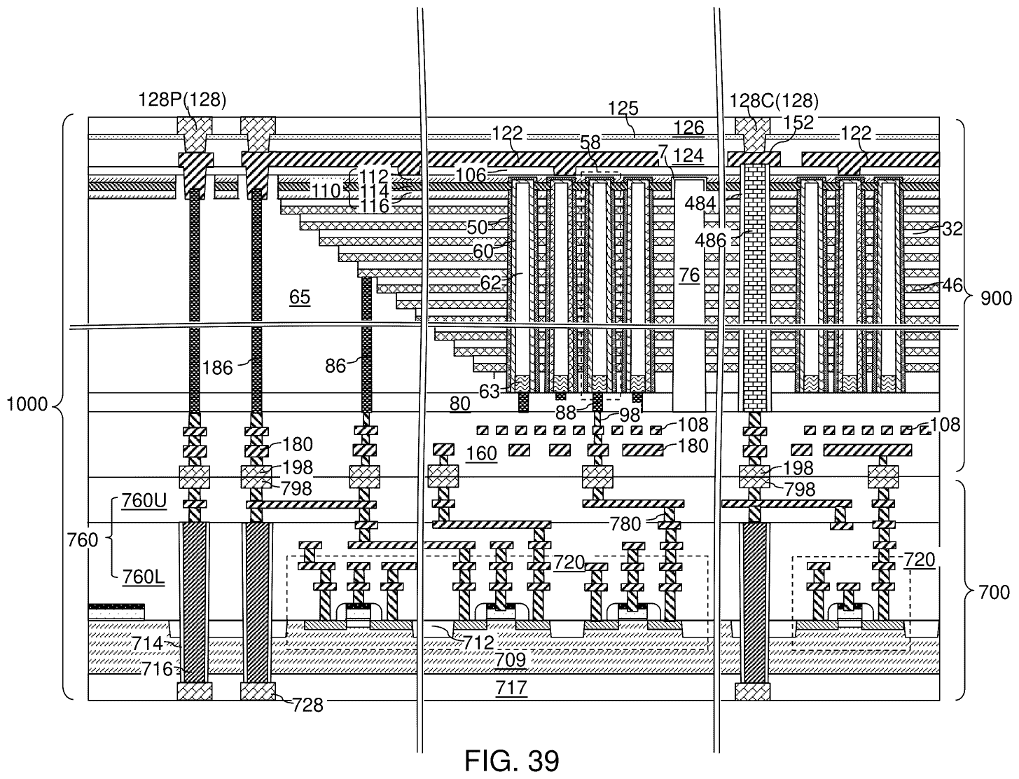

Referring to FIG. 39, the carrier substrate 912 and the adhesive layer 911 may be removed by performing the processing steps described with reference to FIG. 31.

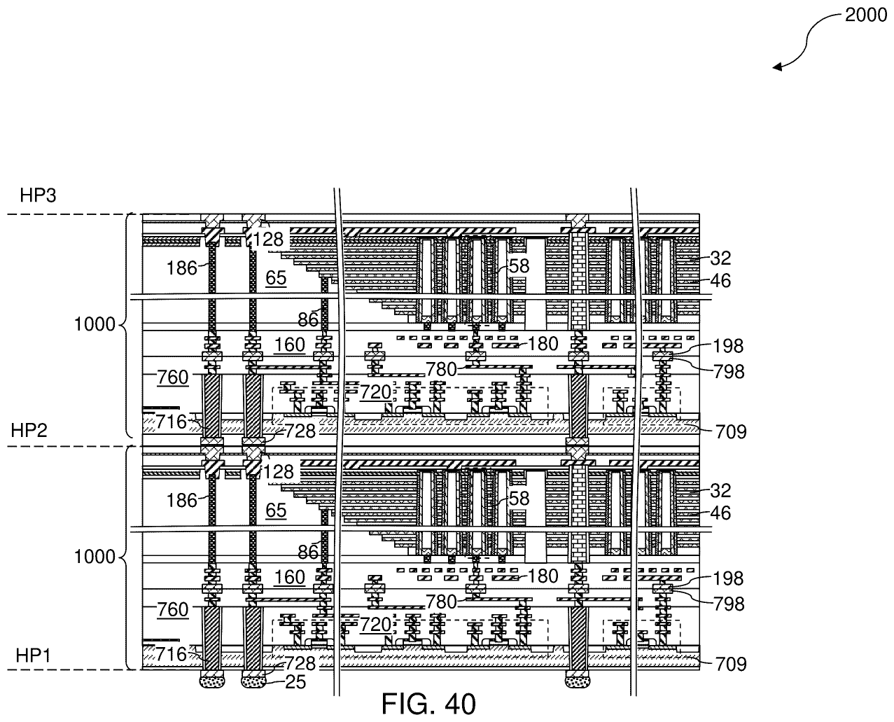

FIGS. 40, 41, 42, and 43 illustrate various embodiments of a vertical stack of bonded assemblies 1000 that can be formed by vertically stacking multiple instances of the unit bonded assembly 1000 (i.e., the bonded assembly 1000) illustrated in FIG. 39.

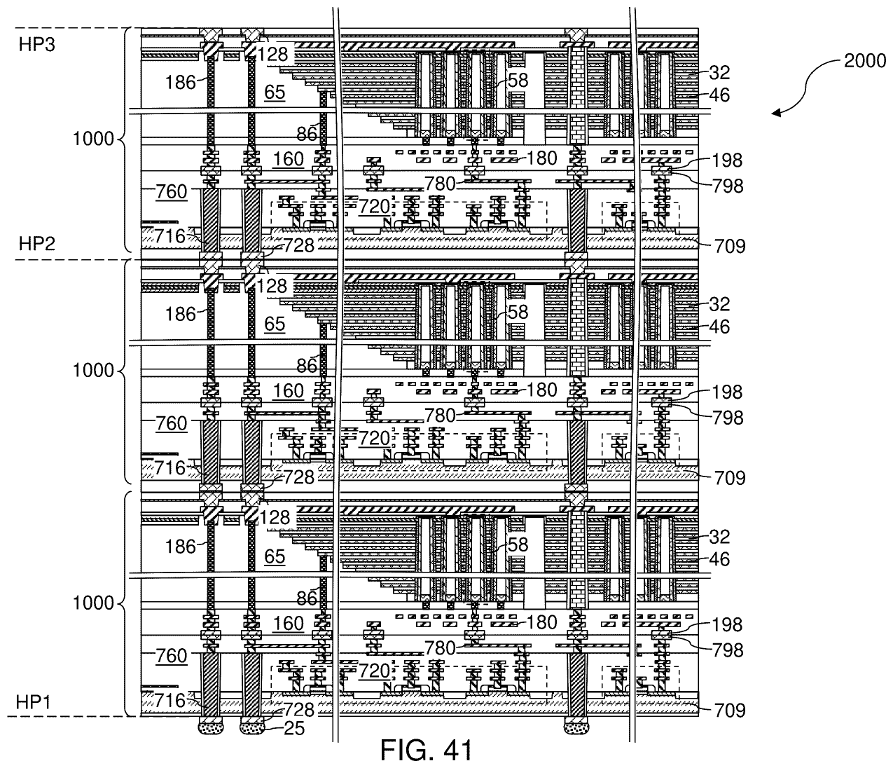

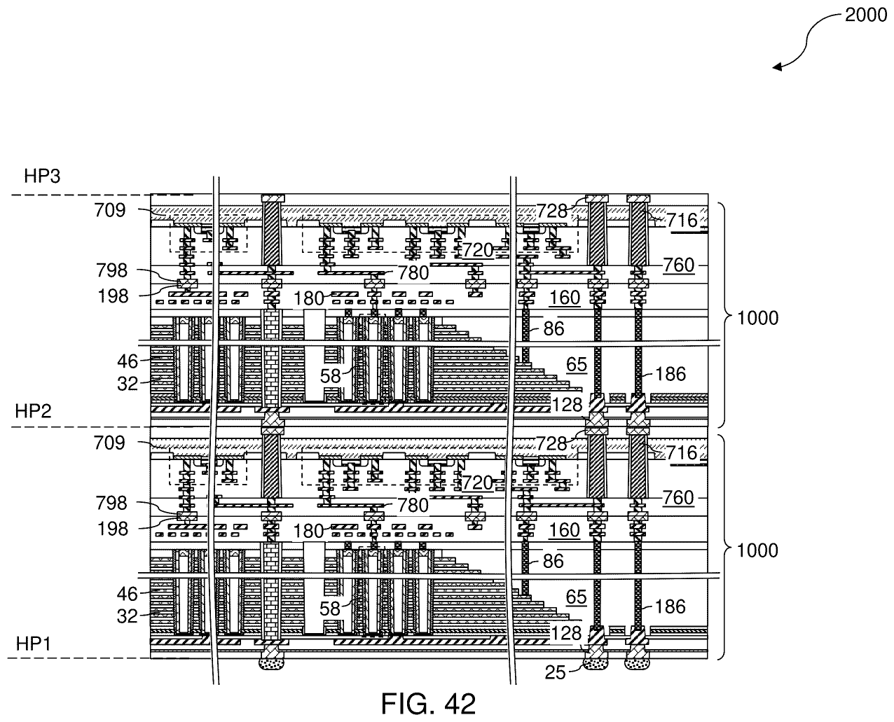

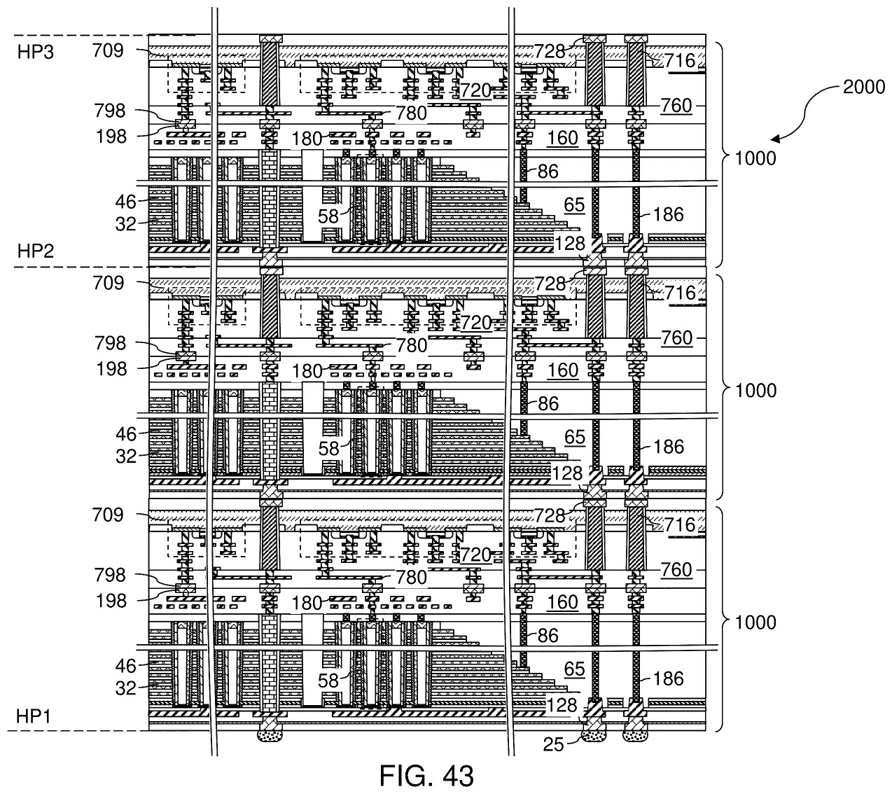

FIG. 40 is a vertical cross-sectional view of a third exemplary vertical stack of two bonded assemblies 1000 configured for bonding with a semiconductor package structure via metal-to-metal bonding such that solder material portions 25 are formed on an outermost memory-controller die 700. FIG. 41 is a vertical cross-sectional view of a fourth exemplary vertical stack of three bonded assemblies 1000 configured for bonding with a semiconductor package structure via metal-to-metal bonding such that solder material portions 25 are formed on an outermost memory-controller die 700. FIG. 42 is a vertical cross-sectional view of an alternative configuration of the third exemplary vertical stack of two bonded assemblies 1000 configured for bonding with a semiconductor package structure via metal-to-metal bonding such that solder material portions 25 are formed on an outermost memory die 900. FIG. 43 is a vertical cross-sectional view of an alternative configuration of the fourth exemplary vertical stack of three bonded assemblies 1000 configured for bonding with a semiconductor package structure via metal-to-metal bonding such that solder material portions 25 are formed on an outermost memory die 900. The metal-to-metal bonding may comprise wafer to wafer bonding, die to wafer bonding or die to die bonding. In case, the metal-to-metal bonding comprises wafer to wafer bonding, the bonded wafers may be diced after bonding to form the discrete, diced high bandwidth flash memory stack 2000 (i.e., flash memory chip).

Each vertical stack of two or more bonded assemblies 1000 constitutes a high bandwidth flash memory stack 2000. In the exemplary vertical stacks illustrated in FIGS. 40-43, each vertically neighboring pair of unit bonded assemblies 1000 can be bonded to each other via metal-to-metal bonding, such as copper to copper bonding between opposing copper or copper alloy bonding pads. No solder material is present between any vertically neighboring pair of a memory die 900 and a memory-controller die 700 within the entirety of the high bandwidth flash memory stack 2000. The solder material portions 25 are attached to an outermost die within the high bandwidth flash memory stack 2000, and as such, do not constitute a portion of the high bandwidth flash memory stack 2000. The solder material portions 25 may be bonded to the system level logic die 3000, the interposer 4000 or the packaging substrate 5000, as shown in FIG. 36A or 36B.

In the embodiments of the high bandwidth flash memory stack 2000 illustrated in FIGS. 40-43, for each vertically neighboring pair of unit bonded assemblies 1000, memory-die backside bonding structures 128 of a memory die 900 of a first unit bonded assembly 1000 within said each vertically neighboring pair of unit bonded assemblies 1000 are bonded to controller-die backside bonding structures 728 of a memory-controller die 700 of a second unit bonded assembly 1000 within said each vertically neighboring pair of unit bonded assemblies 1000 via metal-to-metal bonding. In one embodiment, for each vertically neighboring pair of unit bonded assemblies 1000, a memory-die backside dielectric layer (106, 124, 125, 126) of the memory die 900 of the first unit bonded assembly 1000 within said each vertically neighboring pair of unit bonded assemblies 1000 is bonded to a controller-die backside dielectric layer 717 of the memory-controller die 700 of the second unit bonded assembly 1000 within said each vertically neighboring pair of unit bonded assemblies 1000 via dielectric-to-dielectric bonding.

Referring to all drawings and according to various embodiments of the present disclosure, a semiconductor structure (2000, 3000, 4000) comprises a plurality of stacked bonded assemblies 1000. Each bonded assembly 1000 of the plurality of bonded assemblies 1000 contains a respective unit bonded assembly 1000 of a respective memory die 900 including a respective three-dimensional array of memory elements (comprising portions of a memory material layer 54) and an array of vertical semiconductor channels 60, and a respective memory-controller die 700 including a respective memory controller circuit 720 configured to control operation of the respective three-dimensional array of memory elements (comprising portions of a memory material layer 54). Each vertically neighboring pair of bonded assemblies 1000 of the plurality of bonded assemblies 1000 is bonded to each other through a respective pair of arrays of bonding structures (198, 798) such that electrically conductive paths vertically extend from a first horizontal plane HP1 including a bottom surface of a bottommost bonded assembly 1000 of the plurality of bonded assemblies 1000 at least to a second horizontal plane HP2 including a bottom surface of a topmost bonded assembly 1000 of the plurality of bonded assemblies 1000.

In one embodiment, the respective memory-controller die 700 further comprises a semiconductor substrate 709 and through-substrate vias 716 which form a part of the electrically conductive paths.

In one embodiment, a bottom surface of a bottommost bonded assembly 1000 comprises bottom bonding structures (128 or 728), and a top surface of the topmost bonded assembly 1000 comprises top bonding structures (728 or 128). Thus, each bonded assembly includes a TSV 716 and/or a bonding structure (128 or 728) both on top and bottom of the bonded assembly 1000 chip. Therefore, the chips can be stacked using micro-bumps or by direct metal-to-metal bonding to form the flash memory stack 2000 using a lower cost, simplified method.

In one embodiment, a memory die 900 is present between each vertically neighboring pair of memory-controller dies 700 within the plurality of bonded assemblies 1000; and a memory-controller die 700 is present between each vertically neighboring pair of memory dies 900 within the plurality of bonded assemblies 1000.

In one embodiment, the respective memory die 900 comprises respective memory-die front bonding structures 198 embedded within respective memory-die front dielectric material layers 160; and the respective memory-controller die 700 comprises respective controller-die front bonding structures 798 embedded within respective controller-die front dielectric material layers 760 and bonded to the respective memory-die front bonding structures 198. In one embodiment, the respective controller-die front bonding structures 798 are bonded to the respective memory-die front bonding structures 198 via metal-to-metal bonding. In one embodiment, a topmost memory-die front dielectric material layer among the respective memory-die front dielectric material layers 160 is bonded to a topmost controller-die front dielectric material layer among the controller-die front dielectric material layers 760 via dielectric-to-dielectric bonding.

In one embodiment, electrically conductive paths vertically extend to a third horizontal plane HP3 including a top surface of the topmost bonded assembly 1000 among the plurality of bonded assemblies 1000.

In one embodiment, each memory die 900 within the plurality of bonded assemblies 1000 comprises a respective memory-die backside dielectric layer (106, 124, 125, 126) embedding respective memory-die backside bonding structures 128; and each memory-controller die 700 within the plurality of bonded assemblies 1000 comprises a respective controller-die backside dielectric layer 717 in contact with respective controller-die backside bonding structures 728.

In one embodiment, for each vertically neighboring pair of unit bonded assemblies 1000, memory-die backside bonding structures 128 of a memory die 900 of a first unit bonded assembly 1000 within said each vertically neighboring pair of unit bonded assemblies 1000 are bonded to controller-die backside bonding structures 728 of a memory-controller die 700 of a second unit bonded assembly 1000 within said each vertically neighboring pair of unit bonded assemblies 1000 via metal-to-metal bonding. In one embodiment, for each vertically neighboring pair of unit bonded assemblies 1000, a memory-die backside dielectric layer (106, 124, 125, 126) of the memory dic 900 of the first unit bonded assembly 1000 within said each vertically neighboring pair of unit bonded assemblies 1000 is bonded to a controller-die backside dielectric layer 717 of the memory-controller die 700 of the second unit bonded assembly 1000 within said each vertically neighboring pair of unit bonded assemblies 1000 via dielectric-to-dielectric bonding.

In one embodiment, for each vertically neighboring pair of unit bonded assemblies 1000, memory-die backside bonding structures 128 of a memory die 900 of a first unit bonded assembly 1000 within said each vertically neighboring pair of unit bonded assemblies 1000 are bonded to controller-die backside bonding structures 728 of a memory-controller die 700 of a second unit bonded assembly 1000 within said each vertically neighboring pair of unit bonded assemblies 1000 through a respective array of solder material portions 25. In one embodiment, a memory-die backside dielectric layer (106, 124, 125, 126) of the memory die 900 of the first unit bonded assembly 1000 within said each vertically neighboring pair of unit bonded assemblies 1000 has a distal surface located within a horizontal plane including bonding surfaces of the memory-die backside bonding structures 128 of the memory die 900 of the first unit bonded assembly 1000.

In one embodiment, each memory die 900 within the plurality of bonded assemblies 1000 comprises a NAND or NOR flash memory die 900 comprising: an alternating stack (32, 46) of insulating layers 32 and electrically conductive layers 46 that alternate along a vertical direction; a two-dimensional array of memory stack structures 55 each containing a respective vertical semiconductor channel 60 of the array of vertical semiconductor channels 60, and a respective vertical stack of memory elements (comprising portions of a memory material layer 54) of the three-dimensional array of memory elements; memory-die backside dielectric layers (106, 124, 125, 126) embedding memory-die backside metal interconnect structures 152; and memory-die backside bonding structures 128 in contact with a distal memory-die backside dielectric layer 126 among the memory-die backside dielectric layers (106, 124, 125, 126).

In one embodiment, each memory die 900 within the plurality of bonded assemblies 1000 comprises through-stack via structures 486 vertically extending at least from a horizontal plane including a bottommost surface of the alternating stack (32, 46) to another horizontal plane including a topmost surface of the alternating stack (32, 46). In one embodiment, each memory die 900 within the plurality of bonded assemblies 1000 comprises a source connection structure 122 electrically connected to the vertical semiconductor channels 60 and embedded within the memory-die backside dielectric layers (106, 124, 125, 126), wherein a subset of the memory-die backside metal interconnect structures 152 is located within openings in the respective source connection structure 122 and provides electrical connection between a subset of the memory-die backside bonding structures 128 and a subset of the through-stack via structures 486.

In one embodiment, the respective memory-controller die 700 within each of the plurality of bonded assemblies 1000 comprises: a respective semiconductor substrate 709, wherein the respective memory controller circuit 720 comprises a respective set of semiconductor devices located on a front surface of the respective semiconductor substrate 709; respective controller-die front dielectric material layers 760 embedding respective controller-die front metal interconnect structures 780 and located on the respective set of semiconductor devices; and a respective controller-die backside dielectric layer 717 located on a backside surface of the respective semiconductor substrate 709.

In one embodiment, the respective memory-controller die 700 within each of the plurality of bonded assemblies 1000 comprises respective through-stack via structures 486 that vertically extend through a subset of the respective controller-die front dielectric material layers 760, the respective semiconductor substrate 709, and at least a portion of the respective controller-die backside dielectric layer 717 and in contact with the respective controller-dic backside dielectric layer 717.

In one embodiment, the semiconductor structure further comprises a system level logic die 3000 that is bonded to the plurality of bonded assemblies 1000 through an array of solder material portions 3025 or through a combination of an interposer 4000 and two arrays of solder material portions (2025, 3025).

Each bonded assembly 1000 chip includes a dedicated memory-controller die 700, and the system level logic die 3000 is not required to directly control the operation of each memory cell in each of the memory dies 900. Therefore, the relatively long electrically conductive paths between the system level logic die 3000 and the dedicated memory-controller die 700 may be used for system level control commands rather than for control of each memory cell, which reduces control signal delay.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a plurality of stacked bonded assemblies, wherein:
each bonded assembly of the plurality of bonded assemblies contains a respective unit bonded assembly of a respective memory die including a respective three-dimensional array of memory elements and an array of vertical semiconductor channels, and a respective memory-controller die including a respective memory controller circuit configured to control operation of the respective three-dimensional array of memory elements; and
each vertically neighboring pair of bonded assemblies of the plurality of bonded assemblies is bonded to each other through a respective pair of arrays of bonding structures such that electrically conductive paths vertically extend from a first horizontal plane including a bottom surface of a bottommost bonded assembly of the plurality of bonded assemblies at least to a second horizontal plane including a bottom surface of a topmost bonded assembly of the plurality of bonded assemblies.

2. The semiconductor structure of claim 1, wherein the respective memory-controller die further comprises a semiconductor substrate and through-substrate vias which form a part of the electrically conductive paths.

3. The semiconductor structure of claim 1, wherein the bottom surface of a bottommost bonded assembly comprises bottom bonding structures, and a top surface of the topmost bonded assembly comprises top bonding structures.

4. The semiconductor structure of claim 1, wherein:
a respective one of the memory dies is present between each vertically neighboring pair of the memory-controller dies within the plurality of bonded assemblies; and
a respective one of the memory-controller dies is present between each vertically neighboring pair of the memory dies within the plurality of bonded assemblies.

5. The semiconductor structure of claim 1, wherein:
the respective memory die comprises respective memory-die front bonding structures embedded within respective memory-die front dielectric material layers; and
the respective memory-controller die comprises respective controller-die front bonding structures embedded within respective controller-die front dielectric material layers and bonded to the respective memory-die front bonding structures.

6. The semiconductor structure of claim 5, wherein the respective controller-die front bonding structures are bonded to the respective memory-die front bonding structures via metal-to-metal bonding.

7. The semiconductor structure of claim 1, wherein the electrically conductive paths vertically extend to a third horizontal plane including a top surface of the topmost bonded assembly of the plurality of bonded assemblies.

8. The semiconductor structure of claim 1, wherein:
each memory die within the plurality of bonded assemblies comprises a respective memory-die backside dielectric layer embedding respective memory-die backside bonding structures; and
each memory-controller die within the plurality of bonded assemblies comprises a respective controller-die backside dielectric layer in contact with respective controller-die backside bonding structures.

9. The semiconductor structure of claim 8, wherein for each vertically neighboring pair of unit bonded assemblies, memory-die backside bonding structures of the memory die of a first unit bonded assembly within said each vertically neighboring pair of unit bonded assemblies are bonded to controller-die backside bonding structures of a memory-controller die of a second unit bonded assembly within said each vertically neighboring pair of unit bonded assemblies via metal-to-metal bonding.

10. The semiconductor structure of claim 8, wherein for each vertically neighboring pair of unit bonded assemblies, memory-die backside bonding structures of a memory die of a first unit bonded assembly within said each vertically neighboring pair of unit bonded assemblies are bonded to controller-die backside bonding structures of a memory-controller die of a second unit bonded assembly within said each vertically neighboring pair of unit bonded assemblies through a respective array of solder material portions.

11. The semiconductor structure of claim 10, wherein a memory-die backside dielectric layer of the memory die of the first unit bonded assembly within said each vertically neighboring pair of unit bonded assemblies has a distal surface located within a horizontal plane including bonding surfaces of the memory-die backside bonding structures of the memory die of the first unit bonded assembly.

12. The semiconductor structure of claim 1, wherein each of the respective memory dies within the plurality of bonded assemblies comprises a NAND or NOR flash memory die comprising:
an alternating stack of insulating layers and electrically conductive layers that alternate along a vertical direction;
a two-dimensional array of memory stack structures each containing a respective vertical semiconductor channel of the array of vertical semiconductor channels and respective vertical stack of the memory elements of the three-dimensional array of memory elements;
memory-die backside dielectric layers embedding memory-die backside metal interconnect structures;
memory-die backside bonding structures in contact with a distal memory-die backside dielectric layer among the memory-die backside dielectric layers;
through-stack via structures vertically extending at least from a horizontal plane including a bottommost surface of the alternating stack to another horizontal plane including a topmost surface of the alternating stack; and
a source connection structure electrically connected to the vertical semiconductor channels and embedded within the memory-die backside dielectric layers;
wherein a subset of the memory-die backside metal interconnect structures is located within openings in the respective source connection structure and provides electrical connection between a subset of the memory-die backside bonding structures and a subset of the through-stack via structures.

13. The semiconductor structure of claim 1, wherein the respective memory-controller die within each of the plurality of bonded assemblies comprises:
a respective semiconductor substrate, wherein the respective memory controller circuit comprises a respective set of semiconductor devices located on a front surface of the respective semiconductor substrate;
respective controller-die front dielectric material layers embedding respective controller-die front metal interconnect structures and located on the respective set of semiconductor devices;
a respective controller-die backside dielectric layer located on a backside surface of the respective semiconductor substrate; and
respective through-stack via structures that vertically extend through a subset of the respective controller-die front dielectric material layers, the respective semiconductor substrate, and at least a portion of the respective controller-die backside dielectric layer and in contact with a respective controller-die backside bonding structure.

14. The semiconductor structure of claim 1, further comprising a system level logic die that is bonded to the plurality of bonded assemblies through an array of solder material portions or through a combination of an interposer and two arrays of solder material portions.

15. A method of forming a semiconductor structure, comprising:
bonding a first memory die to a first memory-controller die to form a first bonded assembly;
bonding second memory die to a second memory-controller die to form a second bonded assembly; and
bonding the first bonded assembly to the second bonded assembly to form a memory stack.

16. The method of claim 15, further comprising:
forming a plurality of memory dies on a first substrate;
forming a plurality of memory-controller dies on a second substrate;
bonding the plurality of the memory dies located on the first substrate to the plurality of the memory-controller dies located on the second substrate; and
dicing the bonded memory dies and memory-controller dies to form a plurality of the bonded assemblies, wherein the first bonded assembly comprises one of the plurality of the bonded assemblies.

17. The method of claim 16, further comprising forming through-substrate vias in the plurality of memory-controller dies.

18. The method of claim 16, wherein:
the first memory die and the second memory die comprise NAND or NOR memory dies;
the first memory die is bonded to the first memory-controller die by metal-to-metal bonding;
the second memory die is bonded to the second memory-controller die by metal-to-metal bonding;
electrically conductive paths vertically extend from a bottom surface of a bottommost bonded assembly of the memory stack to top surface of the topmost bonded assembly in the memory stack;
bottom bonding structures are located on the bottom surface of the bottommost bonded assembly of the memory stack; and
top bonding structures are located on the top surface of the topmost bonded assembly in the memory stack.

19. The method of claim 18, wherein the first bonded assembly is bonded to the second bonded assembly by solder material portions after the step of dicing.

20. The method of claim 18, wherein the first bonded assembly is bonded to the second bonded assembly by metal-to-metal bonding.
